(19) United States
(12) Patent Application Publication
(10) Pub. No.: US 2026/0212809 A1
(43) Pub. Date: Jul. 23, 2026

(54) DISPLAY APPARATUS AND ELECTRONIC DEVICE INCLUDING THE SAME

(71) Applicant: SAMSUNG DISPLAY CO., LTD., YONGIN-SI (KR)

(72) Inventors: Nahyeon Cha, Yongin-si (KR); Junhyun Park, Yongin-si (KR); Hwarang Lee, Yongin-si (KR); Junki Jeong, Yongin-si (KR)

(21) Appl. No.: 19/451,083

(22) Filed: Jan. 16, 2026

(30) Foreign Application Priority Data
Jan. 22, 2025 (KR) 10-2025-0009815

(51) Int. Cl. G09G 3/32

(52) U.S. Cl. CPC G09G 3/32; G09G 2300/0426; G09G 2320/0233; G09G 2330/021

(57) ABSTRACT

A display apparatus includes a substrate, a first-first gate line and a first-second gate line, which are spaced apart from each other and extend in a first direction on the substrate, a data line extending in a second direction, a first pixel circuit and a second pixel circuit, which are disposed along the first direction with the data line therebetween, a first electrode layer connected to a first semiconductor layer of the first transistor, and including a first gap spaced apart from a second gate electrode of the second transistor in a plan view, and a first wire disposed above the first electrode layer, extending in the second direction, and covering at least a portion of the first gap in the plan view.

### CROSS-REFERENCE TO RELATED APPLICATIONS

This application claims priority under 35 U.S.C. § 119 to Korean Patent Application No. 10-2025-0009815, filed on January 22, 2025, the disclosure of which is incorporated by reference herein in its entirety.

### TECHNICAL FIELD

Embodiments of the present disclosure relate to a display apparatus and an electronic device including the same.

### DISCUSSION OF RELATED ART

In recent years, display apparatuses have been developed for a broader range of purposes. At the same time, these devices are becoming thinner and lighter, further expanding their potential applications.

A typical display apparatus includes a display panel, which includes display elements that form pixels, and pixel circuits that control the electrical signals applied to the display elements. Each pixel circuit generally includes a thin-film transistor (TFT), a capacitor, and multiple wires.

As display apparatuses are adapted for increasingly diverse purposes, various design approaches are being explored to improve display quality.

### SUMMARY

Embodiments of the present disclosure include a display apparatus with high reliability, and an electronic device including the same.

According to an embodiment, a display apparatus includes a substrate, a first-first gate line and a first-second gate line, which are spaced apart from each other and extend in a first direction on the substrate, a data line extending in a second direction crossing the first direction, and a first pixel circuit and a second pixel circuit, which are disposed along the first direction with the data line therebetween. The first pixel circuit is connected to the first-first gate line and the second pixel circuit is connected to the first-second gate line. Each of the first pixel circuit and the second pixel circuit includes a first transistor including a first semiconductor layer and a first gate electrode, a second transistor including a second semiconductor layer and a second gate electrode, which are connected to the data line, a first electrode layer connected to the first semiconductor layer, overlapping the first gate electrode, and including a first gap spaced apart from the second gate electrode in a plan view, and a first wire disposed above the first electrode layer, extending in the second direction, and covering at least a portion of the first gap in the plan view.

In an embodiment, each of the first pixel circuit and the second pixel circuit further includes a third semiconductor layer integrated with the second semiconductor layer, and a third gate electrode overlapping the third semiconductor layer. The third gate electrode includes a second gap spaced apart from the first electrode layer in the plan view, and the first wire covers at least a portion of the second gap in the plan view.

In an embodiment, the first wire is branched into a first branch and a second branch, the first branch covers at least a portion of the first gap and the second branch covers at least a portion of the second gap, and the second branch of the first pixel circuit is continuously disposed in an area overlapping the first electrode layer and the second branch of the second pixel circuit includes a disconnected gap in the area overlapping the first electrode layer.

In an embodiment, each of the first pixel circuit and the second pixel circuit further includes a third semiconductor layer integrated with the second semiconductor layer, and a third gate electrode overlapping the third semiconductor layer. The third gate electrode includes a second gap spaced apart from the first electrode layer in the plan view, and the first wire exposes the second gap in the plan view.

In an embodiment, an area of the first wire of the first pixel circuit overlapping the first electrode layer is different from an area of the first wire of the second pixel circuit overlapping the first electrode layer.

In an embodiment, the display apparatus further includes a first emission control line and a second emission control line, which extend in the first direction. The first emission control line includes a third gap that is a portion spaced apart from the first electrode layer in the plan view, and an area of the first wire covering the third gap in the first pixel circuit is about equal to an area of the first wire covering the third gap in the second pixel circuit.

In an embodiment, the second emission control line includes a fourth gap that is a portion spaced apart from the first electrode layer in the plan view, and an area of the first wire covering the fourth gap in the first pixel circuit is about equal to an area of the first wire covering the fourth gap in the second pixel circuit.

In an embodiment, the first electrode layer at least partially overlaps the first emission control line.

In an embodiment, the first pixel circuit and the second pixel circuit share the data line.

In an embodiment, the display apparatus further includes a first light-emitting diode connected to the first pixel circuit, and a second light-emitting diode connected to the second pixel circuit. The first light-emitting diode and the second light-emitting diode emit light of a same color.

In an embodiment, each of the first pixel circuit and the second pixel circuit further includes a holding capacitor, and a capacity of the holding capacitor of the first pixel circuit is different from a capacity of the holding capacitor of the second pixel circuit.

In an embodiment, the holding capacitor includes a first holding electrode disposed below the first semiconductor layer, a second holding electrode disposed in a same layer as the first semiconductor layer, a third holding electrode integrated with the first electrode layer, and a fourth holding electrode disposed above the third holding electrode. The fourth holding electrode is integrated with the first wire.

In an embodiment, the first wire includes a wire configured to transmit a constant voltage.

According to an embodiment of the present disclosure, an electronic device includes a display apparatus. The display apparatus includes a substrate, a first-first gate line and a first-second gate line, which are spaced apart from each other and extend in a first direction on the substrate, a data line extending in a second direction crossing the first direction, and a first pixel circuit and a second pixel circuit, which are disposed along the first direction with the data line therebetween. The first pixel circuit is connected to the first-first gate line and the second pixel circuit is connected to the first-second gate line. Each of the first pixel circuit and the second pixel circuit includes a first transistor including a first semiconductor layer and a first gate electrode, a second transistor including a second semiconductor layer and a second gate electrode, which are connected to the data line, a first electrode layer connected to the first semiconductor layer, overlapping the first gate electrode, and including a first gap spaced apart from the second gate electrode in a plan view, and a first wire disposed above the first electrode layer, extending in the second direction, and covering at least a portion of the first gap in the plan view.

In an embodiment, each of the first pixel circuit and the second pixel circuit further includes a third semiconductor layer integrated with the second semiconductor layer, and a third gate electrode overlapping the third semiconductor layer. The third gate electrode includes a second gap spaced apart from the first electrode layer in the plan view, and an area of the first wire of the first pixel circuit covering the second gap is about equal to an area of the first wire of the second pixel circuit covering the second gap.

In an embodiment, each of the first pixel circuit and the second pixel circuit further includes a holding capacitor, and a capacity of the holding capacitor of the first pixel circuit is different from a capacity of the holding capacitor of the second pixel circuit.

In an embodiment, the electronic device further includes a first emission control line and a second emission control line, which extend in the first direction. The first emission control line includes a third gap that is a portion spaced apart from the first electrode layer in the plan view, and an area of the first wire covering the third gap in the first pixel circuit is about equal to an area of the first wire covering the third gap in the second pixel circuit.

In an embodiment, the first pixel circuit and the second pixel circuit share the data line.

In an embodiment, the first wire includes a wire configured to transmit a constant voltage.

In an embodiment, the electronic device is one of a smartphone, a tablet personal computer (PC), a laptop PC, a television (TV), a desk monitor, smart glasses, a head-mount display, a smart watch, a dashboard of a vehicle, a center fascia, a center information display (CID), and a room mirror display.

### BRIEF DESCRIPTION OF THE DRAWINGS

The above and other features of the present disclosure will become more apparent by describing in detail embodiments thereof with reference to the accompanying drawings, in which:

FIG. 1 is a plan view schematically showing a display apparatus according to an embodiment;

FIG. 2 is an equivalent circuit diagram schematically showing a light-emitting diode that is a light-emitting element corresponding to one pixel of a display apparatus, and a pixel circuit electrically connected to the light-emitting diode, according to an embodiment;

FIG. 3 is a cross-sectional view schematically showing a portion of a display apparatus, according to an embodiment;

FIG. 4 is a plan layout view schematically showing a portion of wires and a pixel circuit, which are disposed in a display area of a display apparatus, according to an embodiment;

FIG. 5 is a layout view schematically showing positions of transistors, a storage capacitor, and a holding capacitor in pixel circuits included in a display apparatus, according to an embodiment;

FIGS. 6 to 10 are layout views schematically showing, for each layer, components such as transistors, a storage capacitor, and a holding capacitor, of the display apparatus of FIG. 5;

FIG. 11 is a plan view of some components of a display apparatus, according to an embodiment;

FIG. 12 is a plan view of some components of a display apparatus, according to an embodiment;

FIG. 13 is a plan view of some components of a display apparatus, according to an embodiment;

FIG. 14 is a plan view of some components of a display apparatus, according to an embodiment;

FIG. 15 is a plan view of some components of a display apparatus, according to an embodiment;

FIG. 16 is a plan view of some components of a display apparatus, according to an embodiment;

FIG. 17 is a plan view of some components of a display apparatus, according to an embodiment;

FIG. 18 is a plan view of some components of a display apparatus, according to an embodiment;

FIG. 19 is a block diagram of an electronic device according to an embodiment; and

FIG. 20 illustrates a plurality of schematic diagrams of electronic devices according to various embodiments.

### DETAILED DESCRIPTION

Embodiments of the present disclosure will be described more fully hereinafter with reference to the accompanying drawings. Like reference numerals may refer to like elements throughout the accompanying drawings.

As used herein, the term "and/or" includes any and all combinations of one or more of the associated listed items. Throughout the disclosure, the expression "at least one of a, b, and c" may indicate only a, only b, only c, both a and b, both a and c, both b and c, all of a, b, and c, or any variations thereof.

It will be understood that the terms “first,” “second,” “third,” etc. are used herein to distinguish one element from another, and the elements are not limited by these terms. Thus, a “first” element in an embodiment may be described as a “second” element in another embodiment.

As used herein, the singular forms “a”, “an” and “the” are intended to include the plural forms as well, unless the context clearly indicates otherwise.

In the following embodiments, the terms such as "comprise" or "include" specify the presence of stated features or components, but do not preclude the addition of one or more other features or components.

It will be understood that when a component is referred to as being “on”, “connected to” (e.g., electrically connected to), “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Spatially relative terms, such as “beneath”, “below”, “lower”, “under”, “above”, “upper”, etc., may be used herein for ease of description to describe one element or feature’s relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

When a certain embodiment may be implemented differently, a specific process order may be performed differently from the described order. For example, two consecutively described processes may be performed substantially at the same time or performed in an order opposite to the described order.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ± 30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

Embodiments of the present disclosure relate to a display apparatus that may improve electrical uniformity and reduce luminance variation in pixel circuits. For example, the display apparatus according to embodiments includes multiple pixel circuits that share a data line, and each pixel circuit includes gate lines, electrode layers, and wires arranged to control parasitic capacitance and reduce current deviations. By strategically controlling how the first wire overlaps specific gaps in the electrode layer and gate electrodes, the display apparatus can maintain consistent electrical characteristics across adjacent pixels.

Embodiments of the present disclosure may enable the adjustment of holding capacitance and parasitic capacitance within pixel circuits to be more uniform, despite variations in structure. This structural consistency may contribute to improved display quality by reducing luminance inconsistencies between adjacent light-emitting elements. The arrangement of shared lines, branched wires, and intentional gap coverage may provide a compact and efficient pixel layout well-suited for high-resolution and thin display panels.

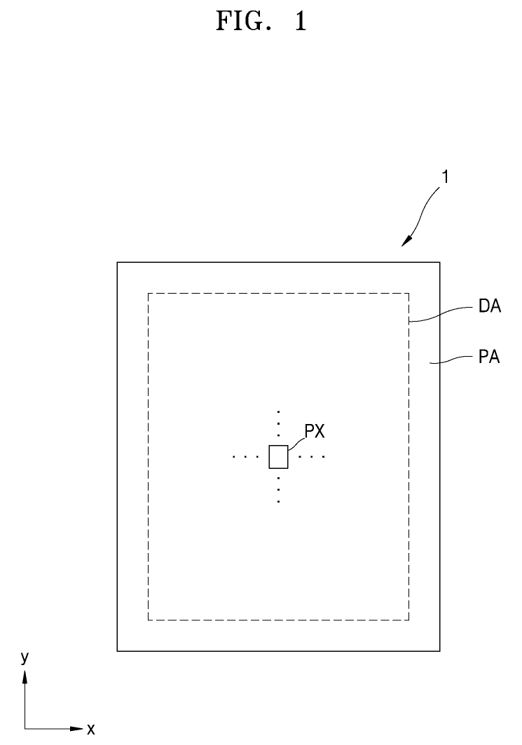

FIG. 1 is a plan view schematically showing a display apparatus 1 according to an embodiment.

Referring to FIG. 1, the display apparatus 1 may include a display area DA and a peripheral area PA disposed outside of the display area DA. The display area DA is a portion in which an image is displayed and may include a plurality of pixels PX. The display area DA may have any one of various shapes, for example, a circle, an oval, a polygon, and a shape of a specific figure. The plurality of pixels PX may be realized by various light-emitting elements such as, for example, an organic light-emitting element, an inorganic light-emitting element, and a quantum dot light-emitting element, where the light-emitting element is driven by being connected to a pixel circuit.

The peripheral area PA of the display apparatus 1 may be disposed outside of the display area DA. A driving integrated circuit (IC) configured to provide an electrical signal to be applied to the display area DA may be disposed in the peripheral area PA, and various wires configured to transmit an electrical signal generated in the driving IC may be disposed in the peripheral area PA.

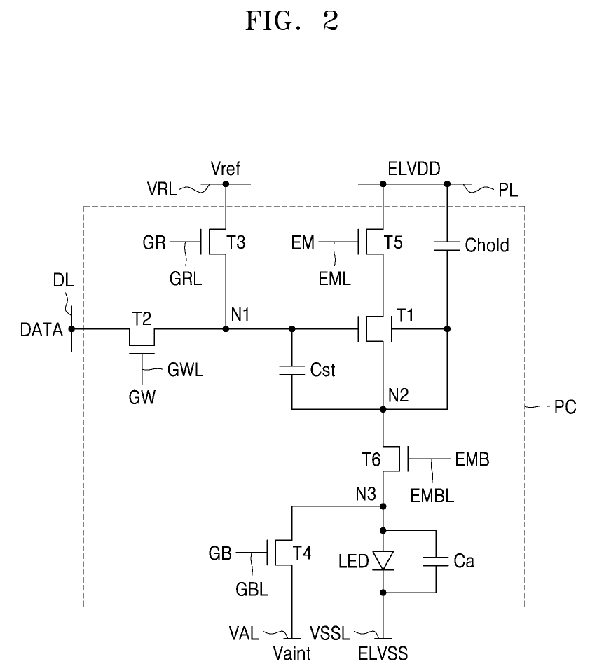

FIG. 2 is an equivalent circuit diagram schematically showing a light-emitting diode LED that is a light-emitting element corresponding to one pixel PX of the display apparatus 1, and a pixel circuit PC electrically connected to the light-emitting diode LED, according to an embodiment.

The pixel circuit PC may be electrically connected to a first gate line GWL configured to transmit a first gate signal GW, a second gate line GRL configured to transmit a second gate signal GR, a third gate line EML configured to transmit a third gate signal EM, a fourth gate line GBL configured to transmit a fourth gate signal GB, a fifth gate line EMBL configured to transmit a fifth gate signal EMB, and a data line DL configured to transmit a data signal DATA. Light emission of the light-emitting diode LED is controlled by the third gate signal EM and the fifth gate signal EMB, and thus, the third gate signal EM and the fifth gate signal EMB may be referred to as emission control signals, and the third gate line EML and the fifth gate line EMBL may be referred to as emission control lines. The third gate line EML may be referred to as a first emission control line and the fifth gate line EMBL may be referred to as a second emission control line.

The pixel circuit PC may be electrically connected to a driving voltage line PL configured to transmit a driving voltage ELVDD, a reference voltage line VRL configured to transmit a reference voltage Vref, and a first initialization voltage line VAL configured to transmit a first initialization voltage Vaint.

The pixel circuit PC may include first to sixth transistors T1 to T6, a storage capacitor Cst, a holding capacitor Chold, and an auxiliary capacitor Ca.

The first transistor T1 may be a driving transistor configured to output a driving current corresponding to the data signal DATA, and the second to sixth transistors T2 to T6 may be switching transistors configured to transmit signals.

According to an embodiment, the first to sixth transistors T1 to T6 may each include an n-channel metal-oxide semiconductor field-effect transistor (MOSFET) (NMOS). Such first to sixth transistors T1 to T6 may each include an oxide semiconductor material. However, the disclosure is not limited thereto, and at least one of the first to sixth transistors T1 to T6 may include a p-channel MOSFET (PMOS). Various modifications are possible, for example, the fifth transistor T5 and/or the sixth transistor T6 may be provided as a PMOS transistor and the remaining transistors may be provided as an NMOS transistor.

A first terminal (or a first electrode) and a second terminal (or a second electrode) of each of the first to sixth transistors T1 to T6 may be a source (or a source electrode) or a drain (or a drain electrode) depending on voltages of the first terminal and the second terminal. For example, according to the voltages of the first terminal and the second terminal, the first terminal may be a drain and the second terminal may be a source, or the first terminal may be a source and the second terminal may be a drain. Hereinafter, a node to which a first-first gate electrode of the first transistor T1 is connected may be defined as a first node N1, and a node to which the second terminal of the first transistor T1 is connected may be defined as a second node N2.

The first transistor T1 may be connected to the driving voltage line PL and the light-emitting diode LED. The first transistor T1 may be connected between the fifth transistor T5 and the sixth transistor T6. The first transistor T1 may include a first gate (or a first gate electrode), the first terminal, and the second terminal connected to the second node N2. The first transistor T1 may include a first-first gate connected to the first node N1. The first transistor T1 may further include a first-second gate connected to its second terminal. The first-first gate and the first-second gate may be disposed in different layers while facing each other. For example, the first-first gate and the first-second gate of the first transistor T1 may face each other with a semiconductor layer disposed therebetween. In the present specification, the first gate (or the first gate electrode) of the first transistor T1 may refer to the first-first gate (or the first-first gate electrode) involved in turning the first transistor T1 on or off.

A gate (or the first-first gate) of the first transistor T1 may be connected to the second terminal of the second transistor T2, the first terminal of the third transistor T3, and the storage capacitor Cst. The first-second gate of the first transistor T1 may be connected to the first terminal of the sixth transistor T6, the storage capacitor Cst, and the holding capacitor Chold. The first terminal of the first transistor T1 may be connected to the driving voltage line PL via the fifth transistor T5, and the second terminal thereof may be connected to a pixel electrode of the light-emitting diode LED via the sixth transistor T6. The first terminal of the first transistor T1 may be connected to the second terminal of the fifth transistor T5. The second terminal of the first transistor T1 may be connected to the first terminal of the sixth transistor T6, the storage capacitor Cst, and the holding capacitor Chold. The first transistor T1 may be configured to control the amount of driving current flowing through the light-emitting diode LED by receiving the data signal DATA according to the switching operation of the second transistor T2.

The second transistor T2 may be connected to the data line DL and the first-first gate of the first transistor T1. The second transistor T2 may include a gate connected to the first gate line GWL, the first terminal connected to the data line DL, and the second terminal connected to the first node N1. The second terminal of the second transistor T2 may be connected to the first-first gate of the first transistor T1, the first terminal of the third transistor T3, and the storage capacitor Cst. The second transistor T2 may be turned on by the first gate signal GW transmitted to the first gate line GWL to electrically connect the data line DL and the first node N1 to each other, and may be configured to transmit the data signal DATA transmitted to the data line DL to the first node N1.

The third transistor T3 may be connected to the first-first gate of the first transistor T1 and the reference voltage line VRL. The third transistor T3 may include a gate connected to the second gate line GRL, the first terminal connected to the first node N1, and the second terminal connected to the reference voltage line VRL. The first terminal of the third transistor T3 may be connected to the first-first gate of the first transistor T1, the second terminal of the second transistor T2, and the storage capacitor Cst. The third transistor T3 may be turned on by the second gate signal GR transmitted to the second gate line GRL to transmit the reference voltage Vref transmitted to the reference voltage line VRL to the first node N1.

The fourth transistor T4 may be connected to the sixth transistor T6 and the first initialization voltage line VAL. The fourth transistor T4 may be connected between the light-emitting diode LED and the first initialization voltage line VAL. The fourth transistor T4 may include a gate connected to the fourth gate line GBL, the first terminal connected to a third node N3, and the second terminal connected to the first initialization voltage line VAL. The first terminal of the fourth transistor T4 may be connected to the second terminal of the sixth transistor T6 and the pixel electrode of the light-emitting diode LED. The fourth transistor T4 may be turned on by the fourth gate signal GB transmitted to the fourth gate line GBL to transmit the first initialization voltage Vaint transmitted to the first initialization voltage line VAL, to the third node N3, and initialize the pixel electrode (e.g., an anode) of the light-emitting diode LED.

The fifth transistor T5 may be connected to the driving voltage line PL and the first transistor T1. The fifth transistor T5 may include a gate connected to the third gate line EML, the first terminal connected to the driving voltage line PL, and the second terminal connected to the first terminal of the first transistor T1. The fifth transistor T5 may be turned on or off according to the third gate signal EM transmitted to the third gate line EML.

The sixth transistor T6 may be connected to the first transistor T1 and the light-emitting diode LED. The sixth transistor T6 may be connected between the second node N2 and the third node N3. The sixth transistor T6 may include a gate connected to the fifth gate line EMBL, the first terminal connected to the second node N2, and the second terminal connected to the third node N3. The first terminal of the sixth transistor T6 may be connected to the second terminal of the first transistor T1, the storage capacitor Cst, and the holding capacitor Chold. The second terminal of the sixth transistor T6 may be connected to the first terminal of the fourth transistor T4 and the pixel electrode of the light-emitting diode LED. The sixth transistor T6 may be turned on or off according to the fifth gate signal EMB transmitted to the fifth gate line EMBL.

The storage capacitor Cst may be connected between the first-first gate of the first transistor T1 and the second terminal of the first transistor T1. A first electrode of the storage capacitor Cst may be connected to the first node N1 and a second electrode thereof may be connected to the second node N2. The first electrode of the storage capacitor Cst may be connected to the first-first gate of the first transistor T1, the second terminal of the second transistor T2, and the first terminal of the third transistor T3. A second electrode of the storage capacitor Cst may be connected to the second terminal and the first-second gate of the first transistor T1, a second electrode of the holding capacitor Chold, and the first terminal of the sixth transistor T6. The storage capacitor Cst may store a data voltage obtained by compensating for a threshold voltage of the first transistor T1.

The first transistor T1 may be turned on when the third transistor T3 and the fifth transistor T5 are turned on. When a voltage of the second terminal of the first transistor T1 is decreased to a difference Vref-Vth1 between the reference voltage Vref and a threshold voltage Vth1 of the first transistor T1, the first transistor T1 is turned off, and a voltage corresponding to the threshold voltage Vth1 of the first transistor T1 is stored in the storage capacitor Cst, and thus, the threshold voltage Vth1 of the first transistor T1 may be compensated for.

The holding capacitor Chold may be connected between the driving voltage line PL and the second node N2. A first electrode of the holding capacitor Chold may be connected to the driving voltage line PL. The second electrode of the holding capacitor Chold may be connected to the second terminal and the first-second gate of the first transistor T1, the second electrode of the storage capacitor Cst, and the first terminal of the sixth transistor T6. The holding capacitor Chold may store a compensation voltage for compensating for the threshold voltage Vth1 of the first transistor T1.

The capacitance of each of the storage capacitor Cst and the holding capacitor Chold may vary according to a color of light emitted from the light-emitting diode LED.

The auxiliary capacitor Ca may be electrically connected to the sixth transistor T6, a sustain voltage line VSSL and the pixel electrode of the light-emitting diode LED. The auxiliary capacitor Ca may prevent an issue in which black luminance is increased when the sixth transistor T6 is turned off, by storing and sustaining a voltage corresponding to a voltage difference between the pixel electrode of the light-emitting diode LED and the sustain voltage line VSSL.

The light-emitting diode LED may be connected to the first transistor T1 through the sixth transistor T6. The light-emitting diode LED may include the pixel electrode (anode) connected to the third node N3 and an opposing electrode (cathode) facing the pixel electrode, and the opposing electrode may receive a common voltage ELVSS. According to an embodiment, the opposing electrode (cathode) may extend to a display area to be electrically connected to the sustain voltage line VSSL configured to provide the common voltage ELVSS. The driving current output by the first transistor T1 flows through the light-emitting diode LED by the turned-on fifth transistor T5 and the turned-on sixth transistor T6, and the light-emitting diode LED may emit light of luminance corresponding to the magnitude of the driving current.

As described above, the first to sixth transistors T1 to T6 may include an oxide semiconductor material. Because oxide semiconductors exhibit high carrier mobility and low leakage current, the amount of voltage drop may remain small even during extended driving periods. In other words, the use of oxide semiconductors may help reduce color changes in displayed images that might otherwise result from voltage drops during low-frequency driving, thus enabling stable operation under such conditions. Accordingly, by forming the first to sixth transistors T1 to T6 with oxide semiconductor material, embodiments may provide a display apparatus that can suppress leakage current and simultaneously reduce overall power consumption.

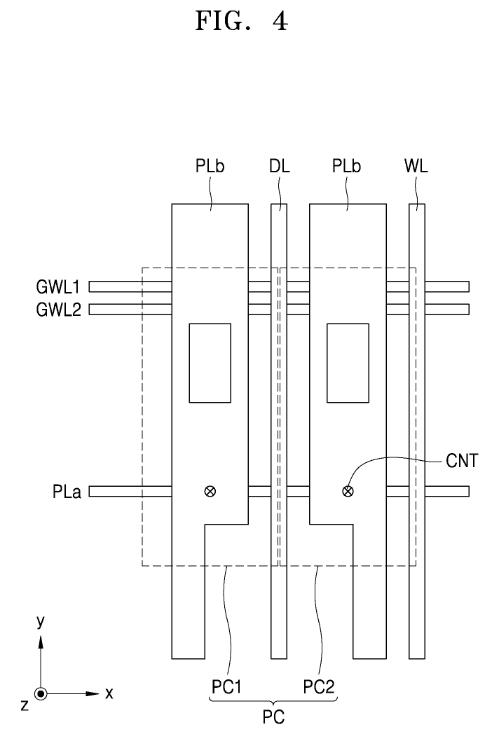

In addition to reducing leakage current and supporting low-frequency operation, the use of oxide semiconductor material in all of the transistors T1 to T6 in embodiments may further contribute to stabilizing current characteristics across pixel circuits that share the data line DL. In embodiments of the present disclosure, the first pixel circuit PC1 (see FIG. 4) and the second pixel circuit PC2 (see FIG. 4) are driven by different gate signals but are symmetrically disposed and electrically balanced using matched parasitic structures. The uniform electrical behavior made possible by oxide semiconductors may help suppress variations in threshold voltage drift and help maintain luminance inconsistency despite differences in gate timing.

FIG. 2 illustrates that the pixel circuit PC includes six transistors, but the disclosure is not limited thereto. For example, according to an embodiment, the number of transistors of the pixel circuit PC may be 5 or less or may be 7 or more.

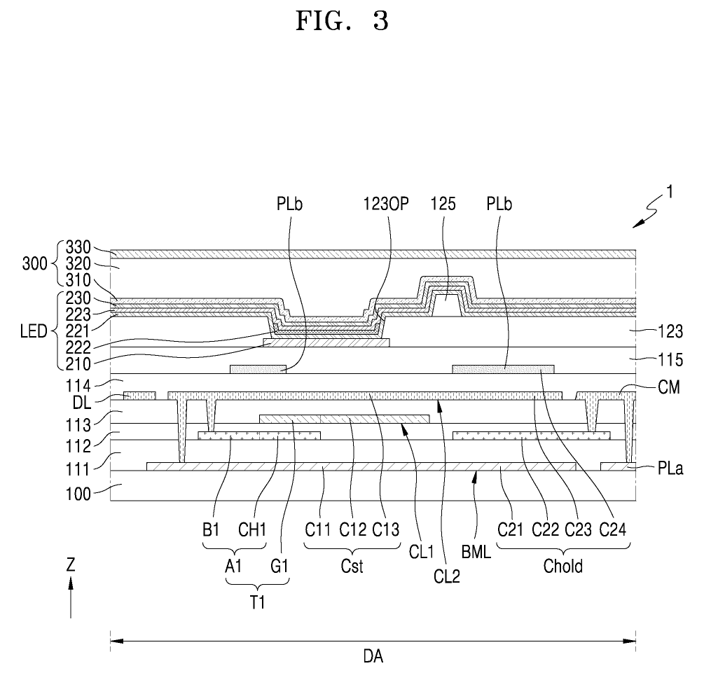

FIG. 3 is a cross-sectional view schematically showing a portion of the display apparatus 1, according to an embodiment.

Referring to FIG. 3, the display apparatus 1 may include the light-emitting diode LED disposed in the display area DA. The light-emitting diode LED is disposed on a substrate 100, and a pixel circuit may be disposed between the substrate 100 and the light-emitting diode LED. According to an embodiment, FIG. 3 illustrates the first transistor T1, the storage capacitor Cst, and the holding capacitor Chold, as some components of the pixel circuit PC. However, the pixel circuit PC is not limited thereto.

The first transistor T1 may include a first semiconductor layer A1 and a first gate electrode G1 overlapping the first semiconductor layer A1. The first transistor T1 may be a driving transistor.

The storage capacitor Cst may include a first storage electrode C11, a second storage electrode C12, and a third storage electrode C13, which are disposed in different layers and overlap each other.

The first storage electrode C11 and the third storage electrode C13 may be connected to each other through a contact hole. The second storage electrode C12 may be connected to the first gate electrode G1. The second storage electrode C12 may be integrated with the first gate electrode G1. The third storage electrode C13 may be connected to the first semiconductor layer A1 through a contact hole.

The holding capacitor Chold may include a first holding electrode C21, a second holding electrode C22, a third holding electrode C23, and a fourth holding electrode C24, which are disposed in different layers and overlap each other.

The first holding electrode C21 and the third holding electrode C23 may be connected to each other through a contact hole. The second holding electrode C22 and the fourth holding electrode C24 may receive the same constant voltage. The first holding electrode C21 may be connected to the first storage electrode C11. The first holding electrode C21 may be integrated with the first storage electrode C11. The second holding electrode C22 may be disposed in a same layer as the first semiconductor layer A1. The third holding electrode C23 may be integrated with the third storage electrode C13. The fourth holding electrode C24 may be integrated with a first wire PLb.

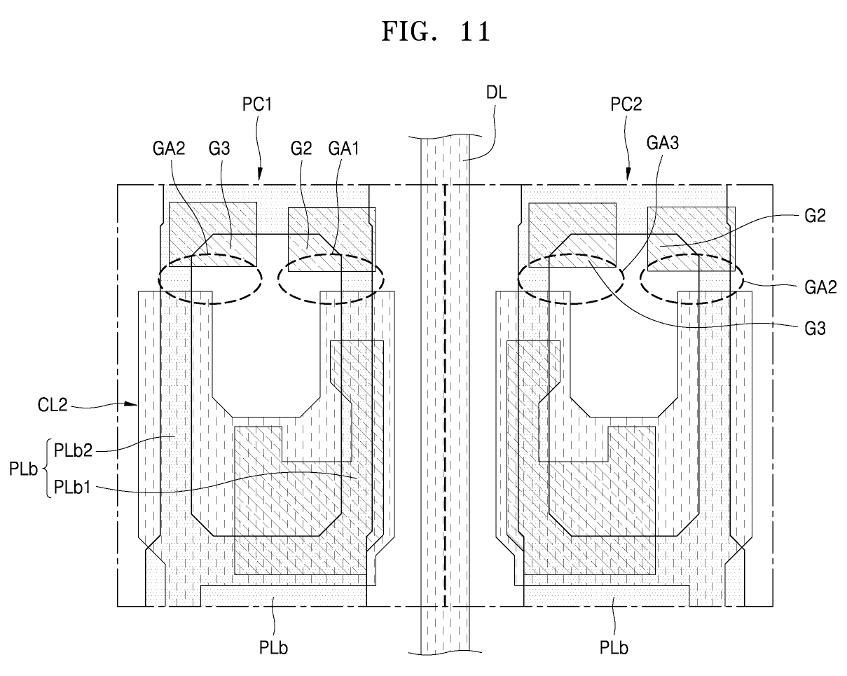

For example, as further described below with reference to FIGS. 11 to 13, in an embodiment, the configuration of the holding capacitor Chold, including the integration of the fourth holding electrode C24 with the first wire PLb, may allow the capacitance of the holding capacitor Chold to be adjusted by modifying the degree of overlap between the fourth holding electrode C24 and the underlying third holding electrode C23. This arrangement may enable different holding capacitor values to be applied to adjacent pixel circuits, such as the first pixel circuit PC1 and the second pixel circuit PC2, even when they share a common data line DL. By adjusting the capacitor structure in this way, embodiments may maintain uniform current driving characteristics and reduce deviations in luminance that may result from variations in signal timing.

The substrate 100 may include a glass material or a polymer resin. According to an embodiment, the substrate 100 may have an alternating stack structure of a base layer including a polymer resin and a barrier layer including an inorganic insulating material, such as, for example, silicon oxide or silicon nitride. The polymer resin may include a polymer resin such as, for example, polyether sulfone, polyacrylate, polyether imide, polyethylene naphthalate, polyethylene terephthalate, polyphenylene sulfide, polyimide, polycarbonate, cellulose triacetate, and cellulose acetate propionate.

A lower metal layer BML and a lower driving voltage line PLa may be disposed on the substrate 100. The lower metal layer BML may perform functions of the first storage electrode C11 of the storage capacitor Cst and the first holding electrode C21 of the holding capacitor Chold. In other words, the lower metal layer BML may include the first storage electrode C11 and the first holding electrode C21. The first storage electrode C11 and the first holding electrode C21 may be disposed on the substrate 100.

The lower driving voltage line PLa may be a wire configured to transmit the driving voltage ELVDD (see FIG. 2).

The lower metal layer BML and the lower driving voltage line PLa may include one or more materials such as, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). According to some embodiments, the lower metal layer BML may be a Mo single layer, may have a double layer structure in which a Mo layer and a Ti layer are stacked, or may have a triple layer structure in which a Ti layer, an Al layer, and a Ti layer are stacked.

A first insulating layer 111 may be disposed on the substrate 100 to cover the lower metal layer BML and the lower driving voltage line PLa. In other words, the first insulating layer 111 may cover the first storage electrode C11 of the storage capacitor Cst and the first holding electrode C21 of the holding capacitor Chold. The first insulating layer 111 may include an inorganic insulating material, such as, for example, a silicon oxide, a silicon nitride, or a silicon oxynitride, and may have a single layer or multiplayer structure including the inorganic insulating material. A semiconductor layer may be disposed on the first insulating layer 111.

The semiconductor layer may be disposed on the first insulating layer 111. In this regard, FIG. 3 illustrates that the first semiconductor layer A1 of the first transistor T1 and the second holding electrode C22 of the holding capacitor Chold are disposed on the first insulating layer 111. The first semiconductor layer A1 may include a channel region CH1 and conductive regions disposed on opposite sides of the channel region CH1, and in this regard, FIG. 3 illustrates a first region B1 that is one of the conductive regions, disposed on one side of the channel region CH1. The second holding electrode C22 of the holding capacitor Chold may include a same material as the first semiconductor layer A1 and may be conductive. The second holding electrode C22 may overlap the first holding electrode C21 with the first insulating layer 111 between the second holding electrode C22 and the first holding electrode C21.

The first semiconductor layer A1 and the second holding electrode C22 of the holding capacitor Chold may include at least one oxide semiconductor material such as, for example, indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the first semiconductor layer A1 may include an InSnZnO (ITZO) semiconductor layer or an InGaZnO (IGZO) semiconductor layer. A conductive process according to plasma processing may be performed on a partial area of the first semiconductor layer A1 and the second holding electrode C22.

A second insulating layer 112 may be disposed on the first insulating layer 111 to cover the first semiconductor layer A1 and the second holding electrode C22 of the holding capacitor Chold. The second insulating layer 112 may be disposed on the first semiconductor layer A1 and the second holding electrode C22 of the holding capacitor Chold. The second insulating layer 112 may include an inorganic insulating material, such as, for example, a silicon oxide, a silicon nitride, or a silicon oxynitride, and may have a single layer or multiplayer structure including the inorganic insulating material.

A first conductive layer CL1 may be disposed on the second insulating layer 112. The first conductive layer CL1 may perform functions of the first gate electrode G1 and the second storage electrode C12 of the storage capacitor Cst. In other words, the first conductive layer CL1 may include the first gate electrode G1 and the second storage electrode C12 of the storage capacitor Cst. The first gate electrode G1 may overlap the channel region CH1 of the first semiconductor layer A1 with the second insulating layer 112 between the first gate electrode G1 and the channel region CH1. The second storage electrode C12 may overlap the first storage electrode C11 with the first insulating layer 111 and the second insulating layer 112 between the second storage electrode C12 and the first storage electrode C11.

The first conductive layer CL1 may include one or more materials such as, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). According to some embodiments, the first conductive layer CL1 may be a Mo single layer, may have a double layer structure in which a Mo layer and a Ti layer are stacked, or may have a triple layer structure in which a Ti layer, an Al layer, and a Ti layer are stacked.

A third insulating layer 113 may be disposed on the second insulating layer 112 and cover the first conductive layer CL1. The third insulating layer 113 may be disposed on the first gate electrode G1 and the second storage electrode C12 of the storage capacitor Cst. The third insulating layer 113 may include an inorganic insulating material, such as, for example, a silicon oxide, a silicon nitride, or a silicon oxynitride, and may have a single layer or multiplayer structure including the inorganic insulating material.

A first electrode layer CL2, the data line DL, and a connecting electrode CM may be disposed on the third insulating layer 113. The first electrode layer CL2 may perform functions of the third storage electrode C13 of the storage capacitor Cst and the third holding electrode C23 of the holding capacitor Chold. The first electrode layer CL2 may be connected to the lower metal layer BML and the first region B1 of the first semiconductor layer A1 through contact holes, respectively. In other words, the third storage electrode C13 may be connected to the first storage electrode C11 through a contact hole. The third storage electrode C13 may overlap the second storage electrode C12 with the third insulating layer 113 disposed between the third storage electrode C13 and the second storage electrode C12. The third holding electrode C23 may overlap the second holding electrode C22 with the second insulating layer 112 and the third insulating layer 113 disposed between the third holding electrode C23 and the second holding electrode C22.

The data line DL may be disposed in a same layer as the first electrode layer CL2. The data line DL may be disposed in a same layer as the third storage electrode C13 and the third holding electrode C23. The connecting electrode CM may connect the second holding electrode C22 and the lower driving voltage line PLa to each other through contact holes. In other words, the second holding electrode C22 may be connected to the lower driving voltage line PLa through the connecting electrode CM, and receive a driving voltage that is a constant voltage.

The first electrode layer CL2, the data line DL, and the connecting electrode CM may each include one or more materials such as, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). According to some embodiments, the first electrode layer CL2, the data line DL, and the connecting electrode CM may be a Mo single layer, may have a double layer structure in which a Mo layer and a Ti layer are stacked, or may have a triple layer structure in which a Ti layer, an Al layer, and a Ti layer are stacked.

A fourth insulating layer 114 may be disposed on the third insulating layer 113 and cover the first electrode layer CL2, the data line DL, and the connecting electrode CM. The fourth insulating layer 114 may include an organic insulating material. For example, the fourth insulating layer 114 may include photoresist, benzocyclobutene (BCB), polyimide, hexamethyldisiloxane (HMDSO), polymethylmethacrylate (PMMA), polystyrene, a polymer derivative having a phenol-based group, acryl-based polymer, imide-based polymer, arylether-based polymer, amide-based polymer, fluorine-based polymer, p-xylene-based polymer, vinyl alcohol-based polymer, or a compound thereof.

The first wire PLb may be disposed on the fourth insulating layer 114. In an embodiment, a portion of the first wire PLb may perform a function of the fourth holding electrode C24 of the holding capacitor Chold. In an embodiment, the fourth holding electrode C24 may be provided as a portion of the first wire PLb. The fourth holding electrode C24 may be disposed on the fourth insulating layer 114 and may overlap the third holding electrode C23 with the fourth insulating layer 114 disposed between the fourth holding electrode C24 and the third holding electrode C23. The first wire PLb may be a wire configured to transmit a constant voltage, and may include, for example, a driving voltage line, an initialization voltage line, a sustain voltage line, or a reference voltage line.

According to some embodiments, the overlap area between the first wire PLb and the third holding electrode C23 may be selectively adjusted to modify the effective capacitance of the holding capacitor Chold. Since the first wire PLb may serve both as a constant voltage line and as the fourth holding electrode C24, its layout can be adapted for each pixel circuit to compensate for differences in gate timing or signal interference. For example, in adjacent pixel circuits that share the same data line DL but receive different gate signals, the shape or continuity of the first wire PLb over the third holding electrode C23 may be varied to maintain consistent current driving behavior and reduce the likelihood of luminance deviation.

The first wire PLb and the fourth holding electrode C24 may each include one or more materials such as, for example, aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). According to some embodiments, the first wire PLb and the fourth holding electrode C24 may be a Mo single layer, may have a double layer structure in which a Mo layer and a Ti layer are stacked, or may have a triple layer structure in which a Ti layer, an Al layer, and a Ti layer are stacked.

A fifth insulating layer 115 may be disposed on the fourth insulating layer 114 and cover the first wire PLb and the fourth holding electrode C24. The fifth insulating layer 115 may include an organic insulating material. For example, the fifth insulating layer 115 may include photoresist, benzocyclobutene (BCB), polyimide, hexamethyldisiloxane (HMDSO), polymethylmethacrylate (PMMA), polystyrene, a polymer derivative having a phenol-based group, acryl-based polymer, imide-based polymer, arylether-based polymer, amide-based polymer, fluorine-based polymer, p-xylene-based polymer, vinyl alcohol-based polymer, or a compound thereof.

The light-emitting diode LED may be disposed on the fifth insulating layer 115. The light-emitting diode LED may include a pixel electrode 210, an emission layer 222, and an opposing electrode 230.

The pixel electrode 210 may be disposed on the fifth insulating layer 115. The pixel electrode 210 may include a reflective layer including, for example, silver (Ag), magnesium (Mg), aluminum (Al), platinum (Pt), palladium (Pd), gold (Au), nickel (Ni), neodymium (Nd), iridium (Ir), chromium (Cr), or a compound thereof. According to an embodiment, the pixel electrode 210 may further include a conductive oxide layer on and/or below the reflective layer. The conductive oxide layer may include, for example, indium tin oxide (ITO), indium zinc oxide (IZO), zinc oxide (ZnO), indium oxide (In₂O₃), indium gallium oxide (IGO), and/or aluminum zinc oxide (AZO). According to an embodiment, the pixel electrode 210 may have a three-layer structure of ITO layer/Ag layer/ITO layer.

A bank layer 123 may be disposed on the pixel electrode 210. The bank layer 123 may include an opening 123OP overlapping the pixel electrode 210 and may cover an edge of the pixel electrode 210. The bank layer 123 may include an organic insulating material. According to some embodiments, the bank layer 123 may include a light-transmitting organic insulating material. According to an embodiment, the bank layer 123 may include an organic insulating material including a light-shielding material. According to some embodiments, the bank layer 123 may include a polyimide (PI)-based binder and a pigment in which red, green, and blue are mixed. According to some embodiments, the bank layer 123 may include a cardo-based binder resin and a mixture of a lactam black pigment and a blue pigment. According to some embodiments, the bank layer 123 may include carbon black. The bank layer 123 may enhance contrast of the display apparatus 1.

A spacer 125 may be disposed on the bank layer 123. The spacer 125 may include a material that is different from that of the bank layer 123. For example, the bank layer 123 and the spacer 125 may include different materials, for example, the bank layer 123 may include a negative photosensitive material, whereas the spacer 125 may include a positive photosensitive material, and may be formed through individual mask processes. According to an embodiment, the spacer 125 may include a same material as the bank layer 123 and may be formed together with the bank layer 123 through a same mask process (e.g., a halftone mask process).

The emission layer 222 may include a high-molecular weight organic material or low-molecular weight organic material, which emit light of a certain color. The emission layer 222 may include a material emitting red light, green light, or blue light, according to the light-emitting diode LED.

A functional layer may be further disposed below and/or on the emission layer 222. For example, a first functional layer 221 may be further disposed between the pixel electrode 210 and the emission layer 222, and a second functional layer 223 may be further disposed between the emission layer 222 and the opposing electrode 230 described below. The first functional layer 221 may include a hole transport layer and/or a hole injection layer. The second functional layer 223 may include an electron transport layer and/or an electron injection layer.

The opposing electrode 230 may include a conductive material with a low work function. For example, the opposing electrode 230 may include a (semi-)transparent layer including, for example, Ag, Mg, Al, Pt, Pd, Au, Ni, Nd, Ir, Cr, Li, Ca, or an alloy thereof. The opposing electrode 230 may further include a layer including, for example, ITO, IZO, ZnO, or In₂O₃, on the (semi-)transparent layer including such a material.

Unlike the pixel electrode 210 being individually formed to correspond to the light-emitting diode LED, the opposing electrode 230 may extend to correspond to the pixel electrodes 210. For example, the pixel electrode 210 of one light-emitting diode LED and the pixel electrode 210 of another light-emitting diode LED may be separated and spaced apart from each other, but the opposing electrode 230 overlapping the pixel electrodes 210 may extend to cover the pixel electrodes 210.

An encapsulation layer 300 may be disposed on the light-emitting diode LED and include at least one inorganic encapsulation layer and at least one organic encapsulation layer. According to an embodiment, FIG. 3 illustrates that the encapsulation layer 300 includes a first inorganic encapsulation layer 310, an organic encapsulation layer 320, and a second inorganic encapsulation layer 330.

The first inorganic encapsulation layer 310 and the second inorganic encapsulation layer 330 may include at least one inorganic insulating material such as, for example, aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may be a single layer or multilayer including the above material. The organic encapsulation layer 320 may include a polymer-based material. Examples of the polymer-based material may include an acrylic resin, an epoxy resin, polyimide, and polyethylene. According to an embodiment, the organic encapsulation layer 320 may include acrylate.

FIG. 4 is a plan layout view schematically showing a portion of wires and a pixel circuit, which are disposed in the display area DA of the display apparatus 1, according to an embodiment.

Referring to FIG. 4, the display apparatus 1 may include a first-first gate line GWL1 and a first-second gate line GWL2, which extend in a first direction (an x direction), and the data line DL and a wire WL, which extend in a second direction (a y direction) crossing the first direction. Also, the display apparatus 1 may include the lower driving voltage line PLa extending in the first direction, and the first wire PLb extending in the second direction.

The pixel circuits PC may be disposed along the first direction (e.g., a +x-axis direction and/or a -x-axis direction) and the second direction (e.g., a +y-axis direction and/or a -y-axis direction) in the display area DA, and FIG. 4 illustrates a first pixel circuit PC1 and a second pixel circuit PC2, which are disposed adjacent to each other in a same row, e.g., in an (i)th row.

According to an embodiment, the first pixel circuit PC1 and the second pixel circuit PC2 may share the data line DL. In other words, a second transistor of the first pixel circuit PC1 and a second transistor of the second pixel circuit PC2 may be connected to the same data line DL. The first pixel circuit PC1 and the second pixel circuit PC2 may be disposed along the first direction with the data line DL disposed therebetween. The data line DL may extend in the second direction between the first pixel circuit PC1 and the second pixel circuit PC2.

According to an embodiment, the first pixel circuit PC1 and the second pixel circuit PC2 share one data line DL, and thus, the number of data lines DL may be reduced and accordingly, the number of IC chips configured to provide a data signal may be reduced, thereby reducing power consumption and reducing costs.

Also, by sharing the data line DL, the data line DL may be disposed on one side of the pixel circuits PC and other wires WL may be disposed on the other side of the pixel circuits PC in a same layer as the data line DL, thereby efficiently using available space. For example, the wire WL may be used as an initialization voltage line, a sustain voltage line configured to transmit a common voltage, or the like.

In configurations where adjacent pixel circuits, such as the first pixel circuit PC1 and the second pixel circuit PC2, share a single data line DL, each circuit may be controlled by a different gate line. As a result, signal timing and transistor switching behavior may vary between the two circuits, despite their physical symmetry. While this arrangement may improve wiring efficiency and reduce the number of data lines and driver ICs, it may also introduce electrical imbalances that could lead to inconsistencies in pixel operation or luminance.

To address this, circuit elements such as the holding capacitor Chold may be formed with different capacitance values in the respective pixel circuits according to embodiments. Additionally, layout structures such as the first wire PLb, which is integrated with the fourth holding electrode C24, may be selectively patterned to control the overlap with the underlying electrode layer C23. This approach may allow the electrical behavior of each pixel circuit PC to be fine-tuned based on its gate drive conditions, which may provide stable and uniform display performance even in shared-line architectures.

The first pixel circuit PC1 may be connected to a first light-emitting diode to drive the first light-emitting diode, and the second pixel circuit PC2 may be connected to a second light-emitting diode to drive the second light-emitting diode. According to an embodiment, the first light-emitting diode and the second light-emitting diode may emit light of a same color. In other words, the pixel circuits PC sharing the data line DL may be connected to a light-emitting diode emitting light of a same color. Accordingly, a difference in luminance due to color may be disregarded, and thus, power consumption may be reduced.

The pixel circuits PC sharing the data line DL may receive different gate signals. The first pixel circuit PC1 may be connected to the first-first gate line GWL1 and the second pixel circuit PC2 may be connected to the first-second gate line GWL2. The pixel circuit PC disposed on the left side of the data line DL being shared may be connected to the first-first gate line GWL1, and the pixel circuit PC disposed on the right side of the data line DL being shared may be connected to the first-second gate line GWL2.

The driving voltage line PL may include the lower driving voltage line PLa and the first wire PLb, which are disposed in different layers. In this case, the first wire PLb may be an upper driving voltage line. The lower driving voltage line PLa may extend in the first direction and the first wire PLb that is the upper driving voltage line may extend in the second direction. The lower driving voltage line PLa and the first wire PLb that is the upper driving voltage line may form a mesh structure by being connected to each other through a contact hole CNT. Corresponding to some pixel circuits, the first wire PLb may be an initialization voltage line, a sustain voltage line, a reference voltage line, or a wire configured to transmit a constant voltage. In this case, in an embodiment, the first wire PLb is not connected to the lower driving voltage line PLa.

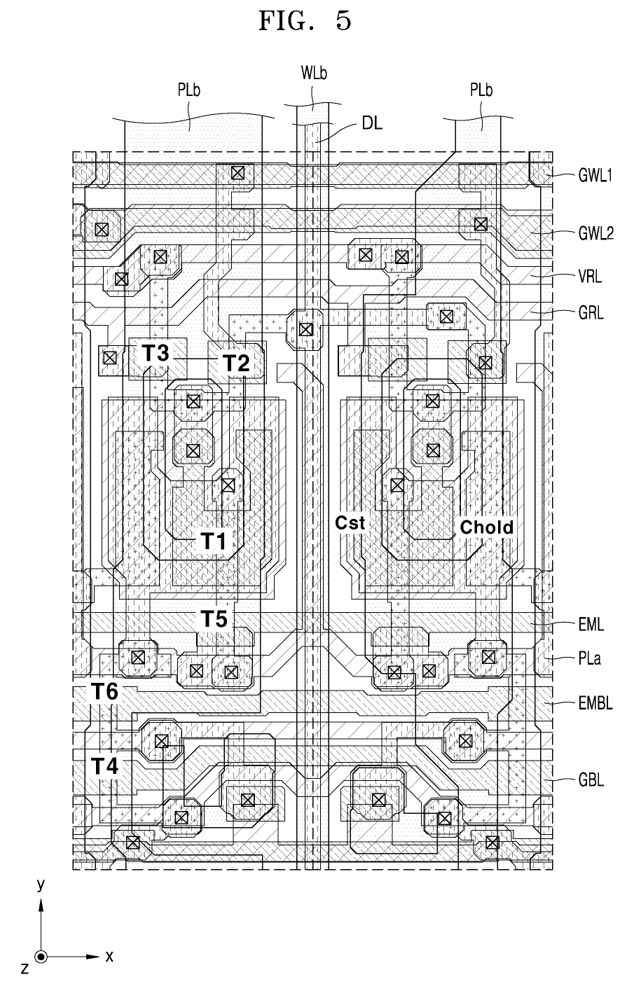

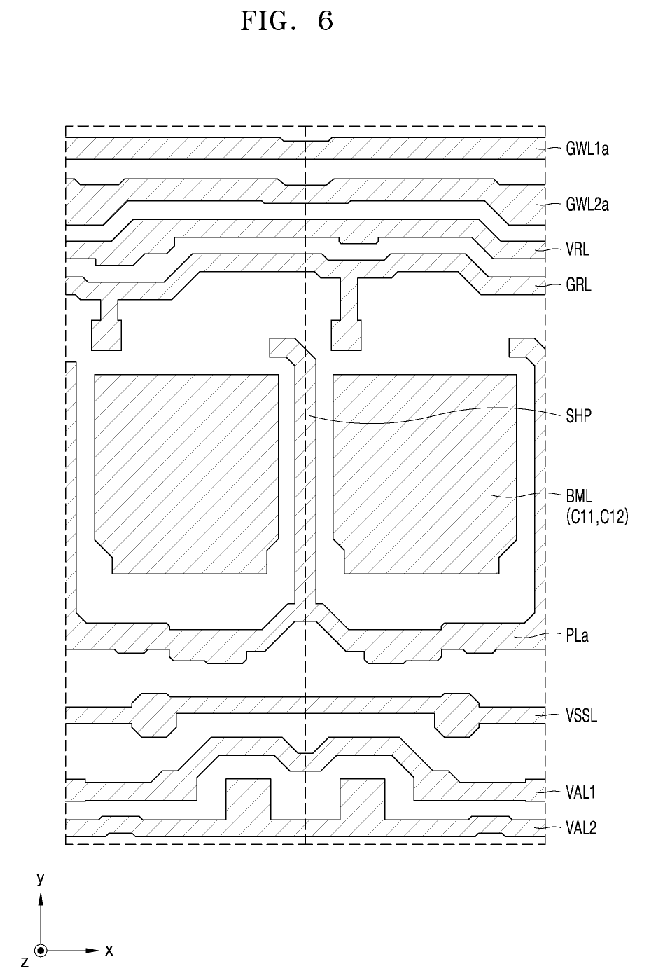

FIG. 5 is a layout view schematically showing positions of the first to sixth transistors T1 to T6, the storage capacitor Cst, and the holding capacitor Chold in pixel circuits included in a display apparatus, according to an embodiment. FIGS. 6 to 10 are layout views schematically showing, for each layer, components such as, for example, the first to sixth transistors T1 to T6, the storage capacitor Cst, and the holding capacitor Chold, of the display apparatus of FIG. 5.

As shown in FIGS. 5 to 10, the display apparatus may include the first pixel circuit PC1 and the second pixel circuit PC2, which are disposed in parallel to each other in the first direction with the data line DL disposed therebetween. A structure shown in FIGS. 5 to 10 may be repeatedly disposed in the first direction (an x-axis direction) and/or the second direction (a y-axis direction).

The first pixel circuit PC1 and the second pixel circuit PC2 may each include the first to sixth transistors T1 to T6, the storage capacitor Cst, and the holding capacitor Chold. Most of the components included in the first pixel circuit PC1 may be symmetrical to the components included in the second pixel circuit PC2, based on the data line DL. According to some embodiments, some components may not be symmetrical. For example, the second transistors T2 and the third transistors T3 may not be symmetrical based on the data line DL. Also, capacities of the storage capacitors Cst and/or the holding capacitors Chold may be different from each other.

Referring to FIGS. 3 and 6, a first-first lower gate line GWL1a, a first-second lower gate line GWL2a, the reference voltage line VRL, the second gate line GRL, the lower metal layer BML, the lower driving voltage line PLa, the sustain voltage line VSSL, a first initialization voltage line VAL1, and a second initialization voltage line VAL2 may be disposed on the substrate 100.

The first-first lower gate line GWL1a, the first-second lower gate line GWL2a, the reference voltage line VRL, the second gate line GRL, the lower driving voltage line PLa, the sustain voltage line VSSL, the first initialization voltage line VAL1, and the second initialization voltage line VAL2 may extend in the first direction (the x direction).

The first-first lower gate line GWL1a may be configured to transmit the first gate signal GW (see FIG. 2) to the first pixel circuit PC1, and the first-second lower gate line GWL2a may be configured to transmit the first gate signal GW to the second pixel circuit PC2. The reference voltage line VRL may be configured to transmit the reference voltage Vref and the second gate line GRL may be configured to transmit a second gate signal. The sustain voltage line VSSL may be configured to transmit the common voltage ELVSS.

The lower driving voltage line PLa may be configured to transmit the driving voltage ELVDD. The lower driving voltage line PLa may include a shield portion SHP protruding in the y direction between the first pixel circuit PC1 and the second pixel circuit PC2. A constant voltage is applied to the shield portion SHP, and thus, interference by an unintentional electrical signal that may be applied to circuit pixels may be blocked.

In pixel layouts where the first pixel circuit PC1 and the second pixel circuit PC2 share a data line DL but are driven by different gate signals, maintaining electrical separation between the circuits typically becomes important for signal integrity. According to embodiments, the shield portion SHP, formed as a protrusion of the lower driving voltage line PLa between the circuits, may help reduce unwanted coupling between adjacent components by applying a constant voltage in the inter-pixel region. This arrangement may contribute to stable current flow in each circuit and support consistent luminance output, even under differing control conditions.

The first initialization voltage line VAL1 may be configured to transmit a first initialization voltage Vint1 to a pixel circuit configured to drive a green pixel and a blue pixel. The second initialization voltage line VAL2 may be configured to transmit a second initialization voltage Vint2 to a pixel circuit configured to drive a red pixel. According to some embodiments, the first initialization voltage Vint1 and the second initialization voltage Vint2 may have different values.

The lower metal layer BML may have an isolated shape and may be disposed for each pixel circuit. The lower metal layer BML may perform functions of the first storage electrode C11 and the first holding electrode C21. The lower metal layer BML may overlap the first semiconductor layer A1 and the first gate electrode G1 described below, and accordingly, incidence of light from the outside to the first semiconductor layer A1 may be prevented or reduced. The lower metal layer BML may function as a lower gate electrode of the first transistor T1.

The first insulating layer 111 (see FIG. 3) may be disposed on the first-first lower gate line GWL1a, the first-second lower gate line GWL2a, the reference voltage line VRL, the lower metal layer BML, the lower driving voltage line PLa, the sustain voltage line VSSL, the first initialization voltage line VAL1, and the second initialization voltage line VAL2.

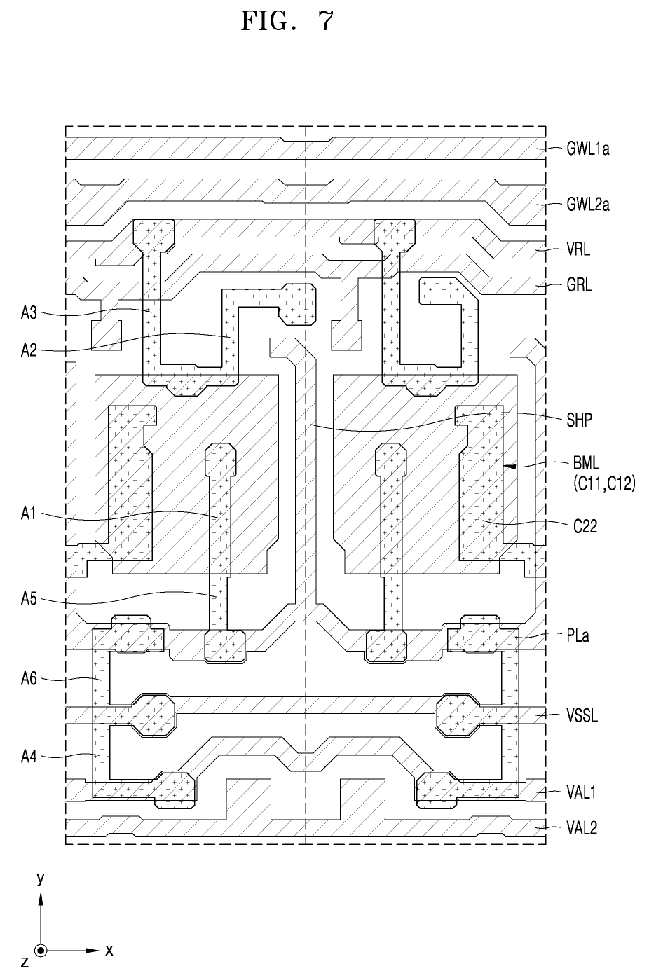

Referring to FIGS. 3 and 7, first to sixth semiconductor layers A1 to A6 and the second holding electrode C22 may be disposed on the first insulating layer 111. The first to sixth semiconductor layers A1 to A6 and the second holding electrode C22 may include a same material.

The first semiconductor layer A1 and the fifth semiconductor layer A5 may be integrally connected to each other. The second semiconductor layer A2 and the third semiconductor layer A3 may be integrally connected to each other. The fourth semiconductor layer A4 and the sixth semiconductor layer A6 may be integrally connected to each other. The first semiconductor layer A1 may be disposed adjacent to the second semiconductor layer A2 and the third semiconductor layer A3, while being separated and spaced apart from the second semiconductor layer A2 and the third semiconductor layer A3. The fifth semiconductor layer A5 may be disposed adjacent to the sixth semiconductor layer A6, while being separated and spaced apart from the sixth semiconductor layer A6.

The second holding electrode C22 may overlap the lower metal layer BML. At least a portion of the lower metal layer BML overlapping the second holding electrode C22 may be the first holding electrode C21 of the holding capacitor Chold. The second holding electrode C22 may have an isolated shape and may be disposed for each pixel circuit. A portion of the second holding electrode C22 may overlap the lower driving voltage line PLa and may be electrically connected to the lower driving voltage line PLa to transmit a driving voltage.

The second insulating layer 112 (see FIG. 3) may be disposed on the structure shown in FIG. 7, for example, on the first to sixth semiconductor layers A1 to A6 and the second holding electrode C22.

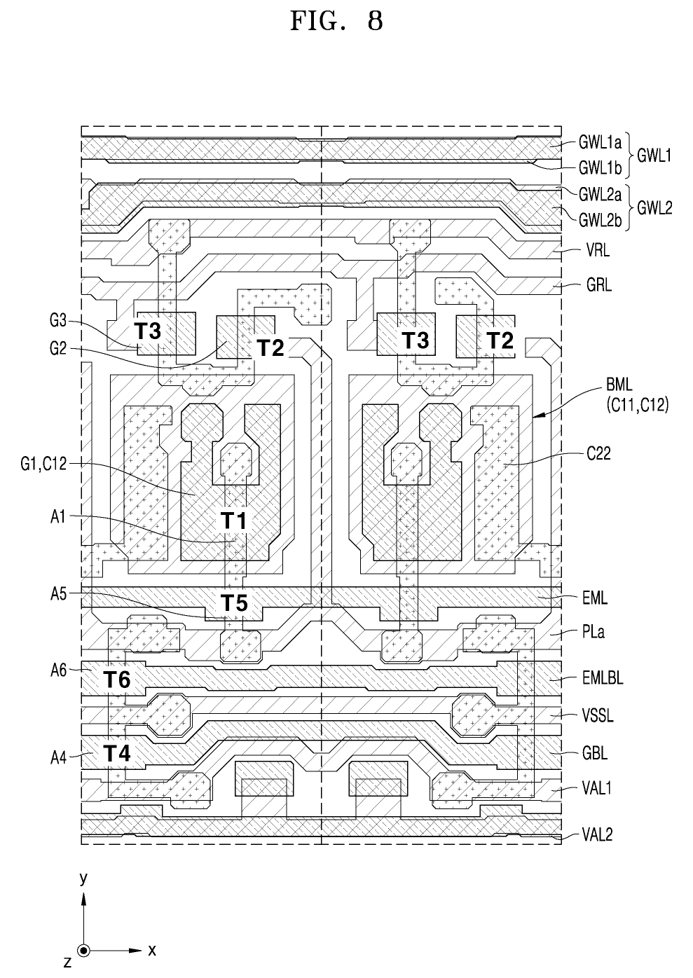

Referring to FIGS. 3 and 8, a first-first upper gate line GWL1b, a first-second upper gate line GWL2b, the third gate line EML, the fourth gate line GBL, the fifth gate line EMBL, the first gate electrode G1, a second gate electrode G2, and a third gate electrode G3 may be disposed on the second insulating layer 112.

The first-first upper gate line GWL1b, the first-second upper gate line GWL2b, the third gate line EML, the fourth gate line GBL, and the fifth gate line EMBL may extend in the first direction (the x direction).

The first-first upper gate line GWL1b may be configured to transmit the first gate signal GW (see FIG. 2) to the first pixel circuit PC1, and the first-second upper gate line GWL2b may be configured to transmit the first gate signal GW to the second pixel circuit PC2. The first-first upper gate line GWL1b may overlap the first-first lower gate line GWL1a. The first-second upper gate line GWL2b may overlap the first-second lower gate line GWL2a. The first-first gate line GWL1 may include the first-first upper gate line GWL1b and the first-first lower gate line GWL1a. The first-second gate line GWL2 may include the first-second upper gate line GWL2b and the first-second lower gate line GWL2a.

The third gate line EML may transmit the third gate signal EM, the fourth gate line GBL may transmit the fourth gate signal GB, and the fifth gate line EMBL may transmit the fifth gate signal EMB. The third gate line EML may be a first emission control line and the fifth gate line EMBL may be a second emission control line.

The first gate electrode G1, the second gate electrode G2, and the third gate electrode G3 may have isolated shapes. The first gate electrode G1 may overlap the first semiconductor layer A1 to form the first transistor T1. The first gate electrode G1 may perform functions of the second storage electrode C12 of the storage capacitor Cst. The first gate electrode G1 may overlap the lower metal layer BML.

The second gate electrode G2 may overlap the second semiconductor layer A2 to form the second transistor T2. The third gate electrode G3 may overlap the third semiconductor layer A3 to form the third transistor T3.

The third gate line EML may overlap the fifth semiconductor layer A5, and a portion of the third gate line EML overlapping the fifth semiconductor layer A5 may perform functions of a fifth gate electrode. The fourth gate line GBL may overlap the fourth semiconductor layer A4, and a portion of the fourth gate line GBL overlapping the fourth semiconductor layer A4 may perform functions of a fourth gate electrode. The fifth gate line EMBL may overlap the sixth semiconductor layer A6, and a portion of the fifth gate line EMBL overlapping the sixth semiconductor layer A6 may perform functions of a sixth gate electrode.

The third insulating layer 113 (see FIG. 3) may be disposed on the structure shown in FIG. 8.

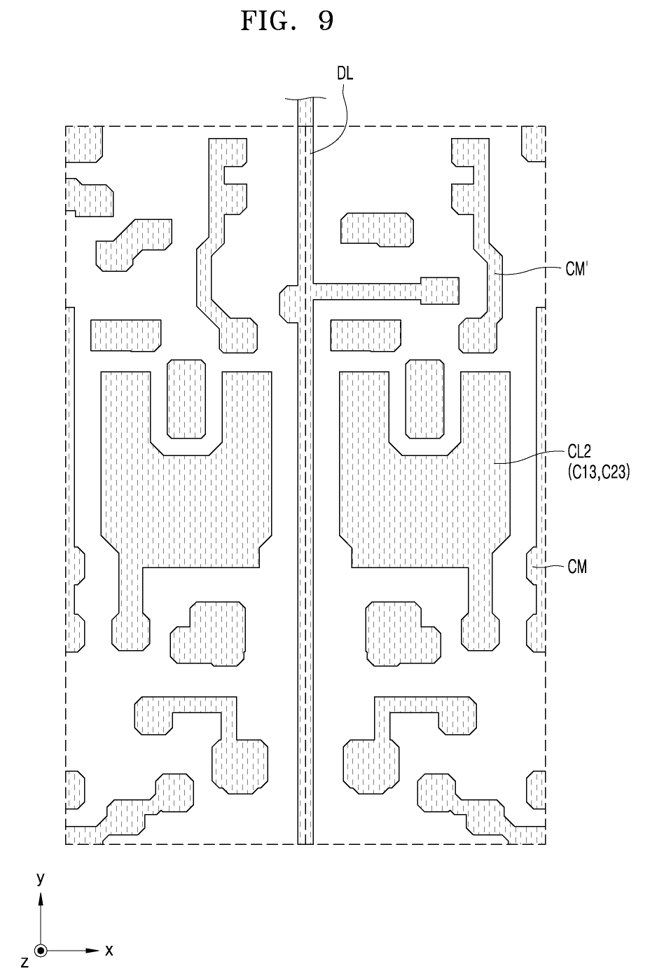

Referring to FIGS. 3 and 9, the data line DL, the first electrode layer CL2, and connecting electrodes CM and CM' may be disposed on the third insulating layer 113. The data line DL, the first electrode layer CL2, and the connecting electrodes CM and CM' may include a same material.

The data line DL may extend in the second direction (the y direction) between the first pixel circuit PC1 and the second pixel circuit PC2. The first pixel circuit PC1 and the second pixel circuit PC2 may share the data line DL.

The first electrode layer CL2 may include the third storage electrode C13 of the storage capacitor Cst and the third holding electrode C23 of the holding capacitor Chold. The connecting electrodes CM and CM' may be used to connect components disposed therebelow to each other. The first electrode layer CL2 and the connecting electrodes CM and CM' may be provided in isolated shapes.

The fourth insulating layer 114 (see FIG. 3) may be disposed on the structure shown in FIG. 9.

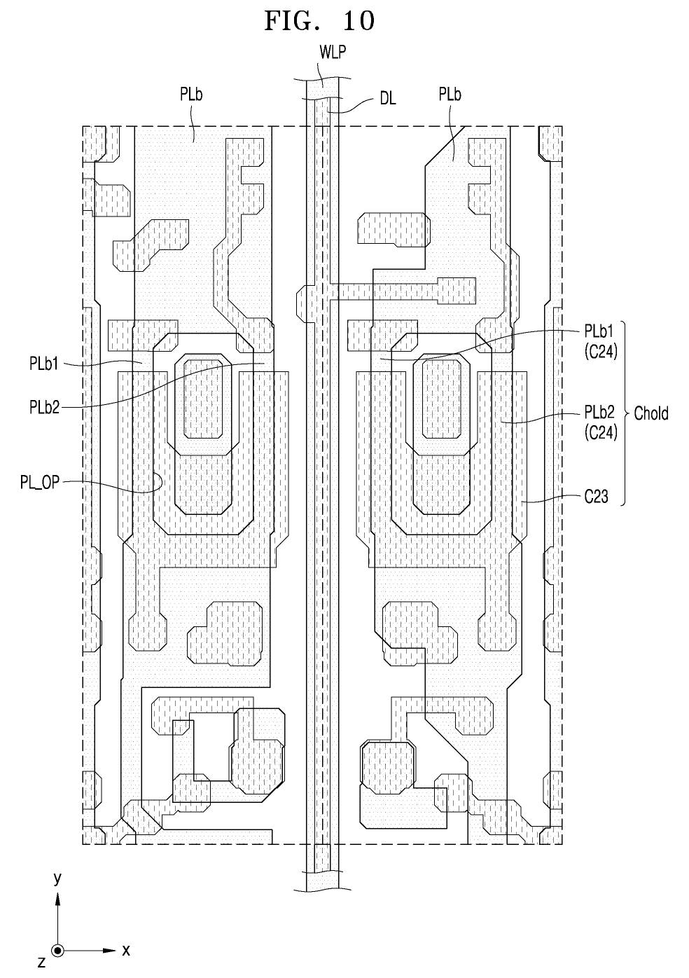

Referring to FIGS. 3 and 10, the first wire PLb may be disposed on the fourth insulating layer 114. The first wire PLb may extend in the second direction. The first wire PLb may overlap the first electrode layer CL2. The first wire PLb may be branched into two branches in an area overlapping the first electrode layer CL2. In an embodiment, the first wire PLb may include a first branch PLb1 and a second branch PLb2. In an embodiment, the first wire PLb may include an opening PL_OP from which a center portion is removed in the area overlapping the first electrode layer CL2. The first wire PLb disposed on opposite sides of the opening PL_OP may be respectively referred to as the first branch PLb1 and the second branch PLb2. The first branch PLb1 may overlap the second gate electrode G2 of the second transistor T2. The second branch PLb2 may overlap the third gate electrode G3 of the third transistor T3.

The first electrode layer CL2 may perform functions of the third holding electrode C23 of the holding capacitor Chold, and an area of the first wire PLb overlapping the first electrode layer CL2 may perform functions of the fourth holding electrode C24 of the holding capacitor Chold. In other words, the first branch PLb1 and the second branch PLb2 may perform functions of the fourth holding electrode C24 of the holding capacitor Chold.

By varying the geometry of the first wire PLb in the region overlapping the first electrode layer CL2, the effective capacitance of the holding capacitor Chold can be adjusted on a per-pixel-circuit basis. For example, by extending or segmenting the first branch PLb1 or second branch PLb2, the overlap area with the underlying electrode layer may be increased or reduced. This may enable the holding capacitor values to be independently tailored for the first pixel circuit PC1 and the second pixel circuit PC2, even though the circuits share a common data line DL. Such structural flexibility may allow for compensation of differences in gate signal timing or parasitic coupling, and may help maintain uniform electrical and optical behavior across the display.

The first pixel circuit PC1 and the second pixel circuit PC2 are respectively connected to the first-first gate line GWL1 and the first-second gate line GWL2 to individually receive a first gate signal, and due to such a mechanism, there may be a difference in luminance between a first light-emitting diode driven by the first pixel circuit PC1 and a second light-emitting diode driven by the second pixel circuit PC2.

To reduce such a difference in luminance, capacitance of the storage capacitor Cst and/or the holding capacitor Chold of the first pixel circuit PC1 may be different from capacitance of the storage capacitor Cst and/or the holding capacitor Chold of the second pixel circuit PC2.

Dispersion of a current deviation may be reduced by adjusting a value of the capacitance of the storage capacitor Cst and/or the holding capacitor Chold and simultaneously adjusting interference between a gate signal and the first electrode layer CL2 to be the same for each pixel circuit. Embodiments of the present disclosure provide a structure that may reduce such a current deviation.

FIG. 11 is a plan view of some components of a display apparatus, according to an embodiment. For example, FIG. 11 illustrates the second gate electrode G2, the third gate electrode G3, the first electrode layer CL2, and the first wire PLb, which are included in the first pixel circuit PC1 and the second pixel circuit PC2 sharing the data line DL.

Referring to FIG. 11, the first electrode layer CL2 may include a first gap GA1 spaced apart from the second gate electrode G2 in a plan view. Also, the first electrode layer CL2 may include a second gap GA2 spaced apart from the third gate electrode G3 in a plan view.

In an embodiment, the areas of the first wire PLb of the first pixel circuit PC1 covering the first gap GA1 and the second gap GA2 may be the same as the areas of the first wire PLb of the second pixel circuit PC2 covering the first gap GA1 and the second gap GA2.

The first wire PLb may at least partially cover the first gap GA1. The first wire PLb may at least partially cover the second gap GA2. The first wire PLb may be branched into the first branch PLb1 and the second branch PLb2. The first branch PLb1 may be continuously disposed from the second gate electrode G2 to the first electrode layer CL2. The second branch PLb2 may be continuously disposed from the third gate electrode G3 to the first electrode layer CL2. The first wire PLb may be a wire configured to transmit a constant voltage.

Such an arrangement may be applied identically to the first pixel circuit PC1 and the second pixel circuit PC2, which share the data line DL.

A coupling signal may be induced in the first electrode layer CL2 according to gate signals applied to the second gate electrode G2 and the third gate electrode G3. Accordingly, parasitic capacitance may occur in a pixel circuit, which may cause a current deviation in the pixel circuit.

In an embodiment, the first wire PLb covers, with the same area, the first gap GA1 and the second gap GA2 in the first pixel circuit PC1 and the second pixel circuit PC2, thereby adjusting parasitic capacitance formed in the first pixel circuit PC1 and parasitic capacitance formed in the second pixel circuit PC2 to a same value.

Through the arrangement described above, the effect of gate signal coupling on the pixel circuit PC can be controlled by managing the spatial relationship between the gate electrodes and the constant voltage wire PLb. When the parasitic capacitance associated with the first gap GA1 and the second gap GA2 is matched between the first pixel circuit PC1 and the second pixel circuit PC2, the current characteristics of the two circuits can be more closely aligned, despite differences in gate control timing. This may contribute to maintaining consistent luminance across adjacent pixels that share a data line DL but operate under separate gate signal conditions.

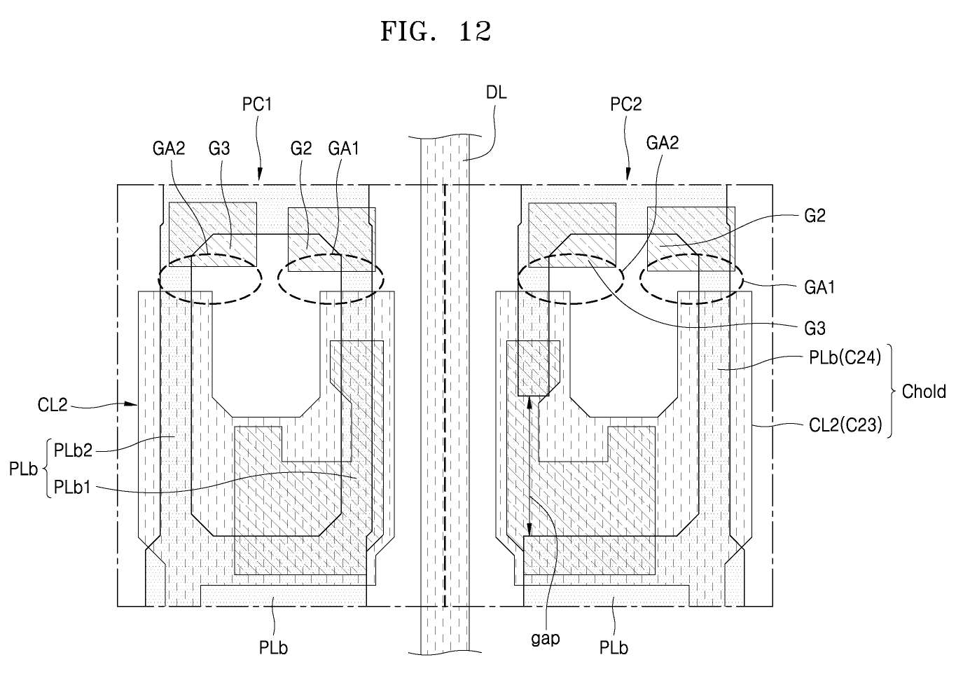

FIG. 12 is a plan view of some components of a display apparatus, according to an embodiment. In FIG. 12, like reference numerals as FIG. 11 refer to like components.

Referring to FIG. 12, the areas of the first wire PLb of the first pixel circuit PC1 covering the first gap GA1 and the second gap GA2 may be the same as the areas of the first wire PLb of the second pixel circuit PC2 covering the first gap GA1 and the second gap GA2.

In an embodiment, the capacitance of the holding capacitor Chold of the first pixel circuit PC1 may be different from the capacitance of the holding capacitor Chold of the second pixel circuit PC2. The holding capacitor Chold may include the fourth holding electrode C24 provided as a portion of the first wire PLb, and the third holding electrode C23 provided as the first electrode layer CL2.

The first branch PLb1 of the fourth holding electrode C24 of the first pixel circuit PC1 may be continuously disposed in an area overlapping the third holding electrode C23. The first branch PLb1 of the fourth holding electrode C24 of the second pixel circuit PC2 may include a disconnected gap in the area overlapping the third holding electrode C23. Accordingly, the capacitance of the holding capacitor Chold of the first pixel circuit PC1 may be greater than the capacitance of the holding capacitor Chold of the second pixel circuit PC2. The capacitance of the holding capacitor Chold may be adjusted such that a luminance deviation of a light-emitting diode connected to each pixel circuit is reduced.

In this manner, according to embodiments, the physical patterning of the fourth holding electrode C24, through branching or segmenting of the first branch PLb1, can be selectively varied between pixel circuits PC that otherwise share structural symmetry. Such an approach may allow the capacitance of the holding capacitor Chold to be tailored for each pixel circuit PC individually, even when the parasitic capacitance from gate signal coupling is equivalent. By doing so, the pixel drive current can be modulated to compensate for variations in circuit behavior that may arise from differences in gate signal timing or signal delays. As a result, uniform luminance output across the first and second pixel circuits PC1 and PC2 may be achieved, despite operating under asynchronous control.

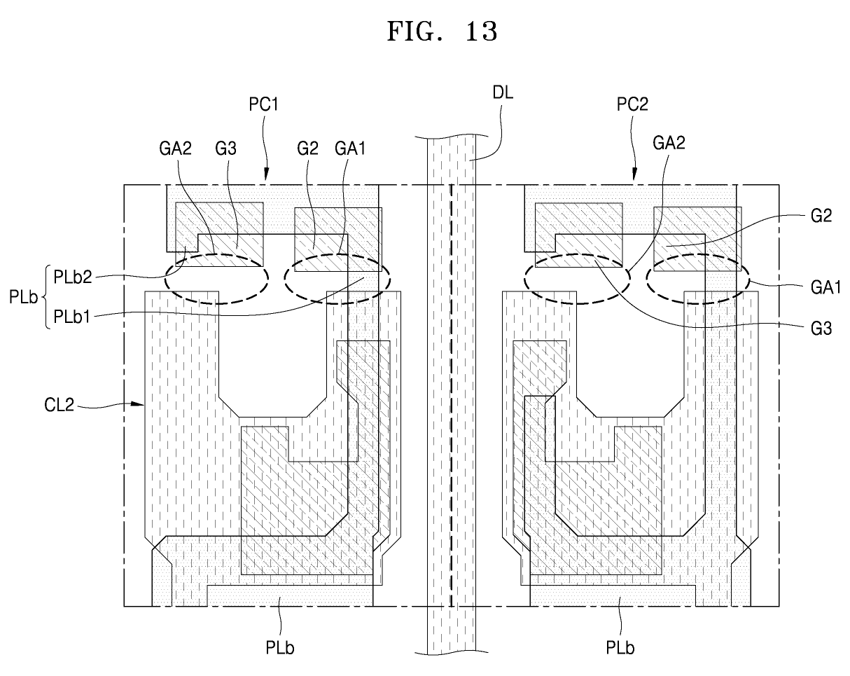

FIG. 13 is a plan view of some components of a display apparatus, according to an embodiment. In FIG. 13, like reference numerals as FIG. 11 refer to like components.

Referring to FIG. 13, the areas of the first wire PLb of the first pixel circuit PC1 covering the first gap GA1 and the second gap GA2 may be the same as the areas of the first wire PLb of the second pixel circuit PC2 covering the first gap GA1 and the second gap GA2.

In an embodiment, the first wire PLb may at least partially cover the first gap GA1. The first wire PLb may expose the second gap GA2 instead of covering the second gap GA2. In other words, the second gap GA2 of the second pixel circuit PC2 may also be exposed by the first wire PLb, like the second gap GA2 of the first pixel circuit PC1 being exposed by the first wire PLb.

The first wire PLb may be branched into the first branch PLb1 and the second branch PLb2. The first branch PLb1 may be continuously disposed from the second gate electrode G2 to the first electrode layer CL2. The second branch PLb2 may expose the second gap GA2.

In an embodiment, the area of the first wire PLb of the first pixel circuit PC1 overlapping the first electrode layer CL2 may be different from the area of the first wire PLb of the second pixel circuit PC2 overlapping the first electrode layer CL2. The area of the second branch PLb2 of the first pixel circuit PC1 exposing the first electrode layer CL2 may be greater than the area of the second branch PLb2 of the second pixel circuit PC2 exposing the first electrode layer CL2.

This may indicate that the capacitance of the holding capacitor Chold of the first pixel circuit PC1 is different from the capacitance of the holding capacitor Chold of the second pixel circuit PC2.

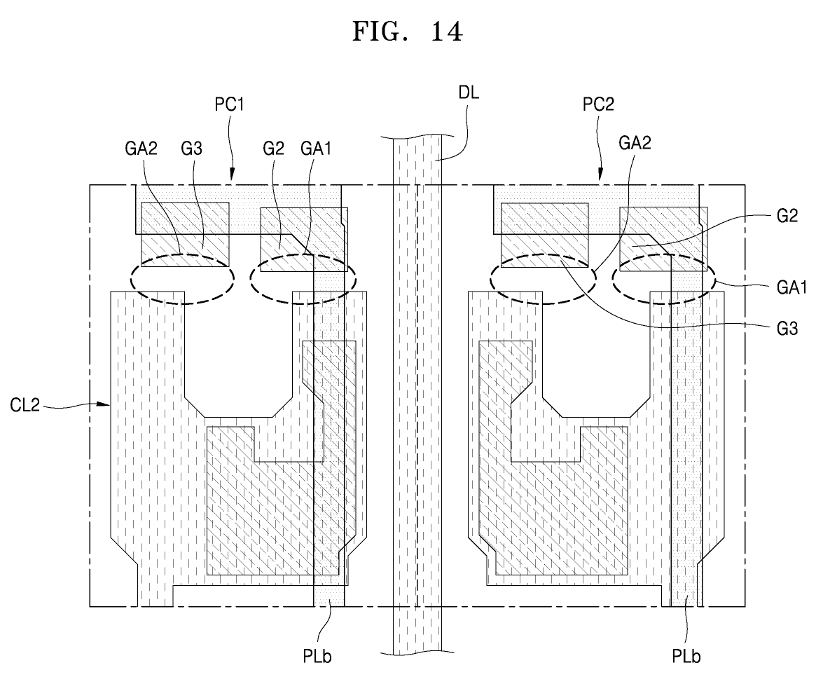

FIG. 14 is a plan view of some components of a display apparatus, according to an embodiment. In FIG. 14, like reference numerals as FIG. 11 refer to like components.

Referring to FIG. 14, the areas of the first wire PLb of the first pixel circuit PC1 covering the first gap GA1 and the second gap GA2 may be the same as the areas of the first wire PLb of the second pixel circuit PC2 covering the first gap GA1 and the second gap GA2.

In an embodiment, the first wire PLb may at least partially cover the first gap GA1. The first wire PLb may expose the second gap GA2 instead of covering the second gap GA2. In other words, the second gap GA2 of the second pixel circuit PC2 may also be exposed by the first wire PLb, like the second gap GA2 of the first pixel circuit PC1 being exposed by the first wire PLb.

The first wire PLb may be provided as one narrow first wire PLb without being branched according to the first electrode layer CL2. Such an arrangement may be provided identically for the first pixel circuit PC1 and the second pixel circuit PC2.

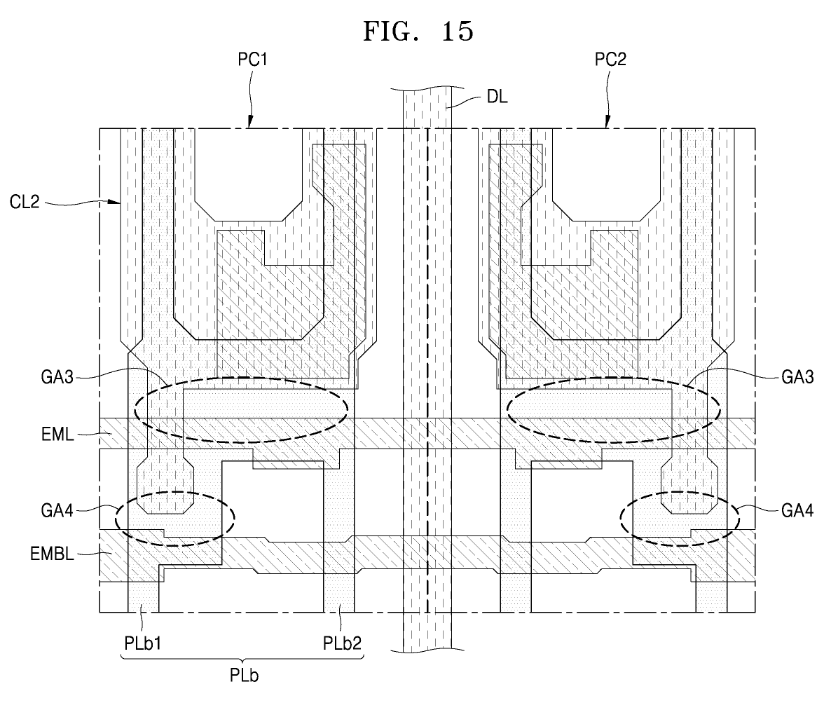

FIG. 15 is a plan view of some components of a display apparatus, according to an embodiment. For example, FIG. 15 illustrates the first electrode layer CL2, the first wire PLb, a first emission control line EML, and a second emission control line EMBL ,which are included in the first pixel circuit PC1 and the second pixel circuit PC2 sharing the data line DL.

Referring to FIG. 15, the first electrode layer CL2 may include a third gap GA3 spaced apart from the first emission control line EML in a plan view. The first electrode layer CL2 may include an area partially overlapping the first emission control line EML. The third gap GA3 may be provided in a remaining area excluding the overlapping area. Also, the first electrode layer CL2 may include a fourth gap GA4 spaced apart from the second emission control line EMBL in a plan view.

In an embodiment, the areas of the first wire PLb of the first pixel circuit PC1 covering the third gap GA3 and the fourth gap GA4 may be the same as the areas of the first wire PLb of the second pixel circuit PC2 covering the third gap GA3 and the fourth gap GA4.

The first wire PLb may cover the third gap GA3 and cover the fourth gap GA4. Such an arrangement may be applied identically to the first pixel circuit PC1 and the second pixel circuit PC2.

A coupling signal may be induced in the first electrode layer CL2 according to gate signals applied to the first emission control line EML and the second emission control line EMBL. Accordingly, parasitic capacitance may occur in a pixel circuit, which may cause a current deviation in the pixel circuit.

In an embodiment, the first wire PLb covers, with the same area, the third gap GA3 and the fourth gap GA4 in the first pixel circuit PC1 and the second pixel circuit PC2, thereby adjusting parasitic capacitor formed in the first pixel circuit PC1 and parasitic capacitor formed in the second pixel circuit PC2 to a same value.

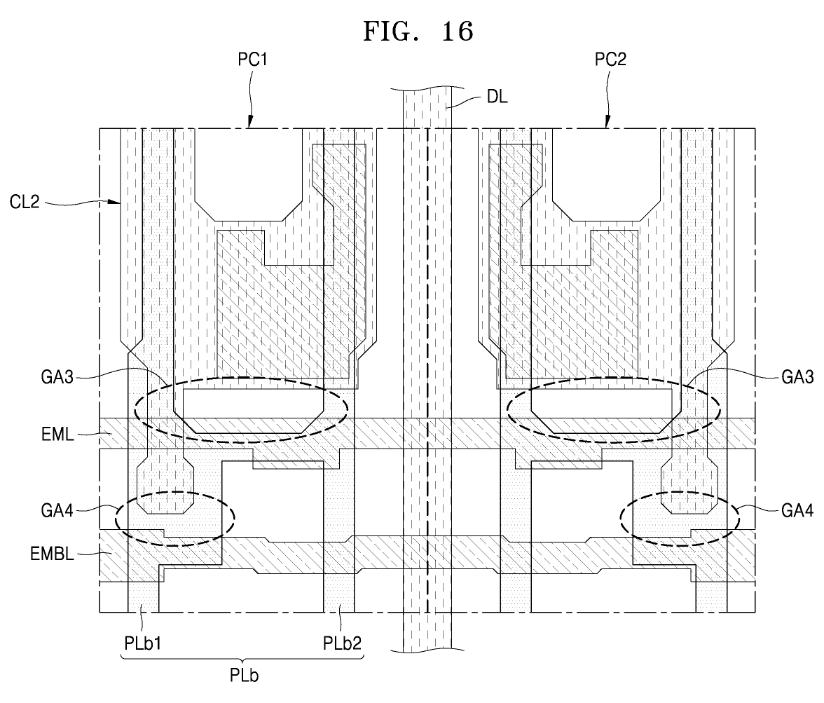

FIG. 16 is a plan view of some components of a display apparatus, according to an embodiment. In FIG. 16, like reference numerals as FIG. 15 refer to like components.

Referring to FIG. 16, the areas of the first wire PLb of the first pixel circuit PC1 covering the third gap GA3 and the fourth gap GA4 may be the same as the areas of the first wire PLb of the second pixel circuit PC2 covering the third gap GA3 and the fourth gap GA4.

The first wire PLb may expose a center portion of the third gap GA3, and cover the fourth gap GA4. Such an arrangement may be applied identically to the first pixel circuit PC1 and the second pixel circuit PC2. Accordingly, same parasitic capacitor may be formed in the first pixel circuit PC1 and the second pixel circuit PC2.

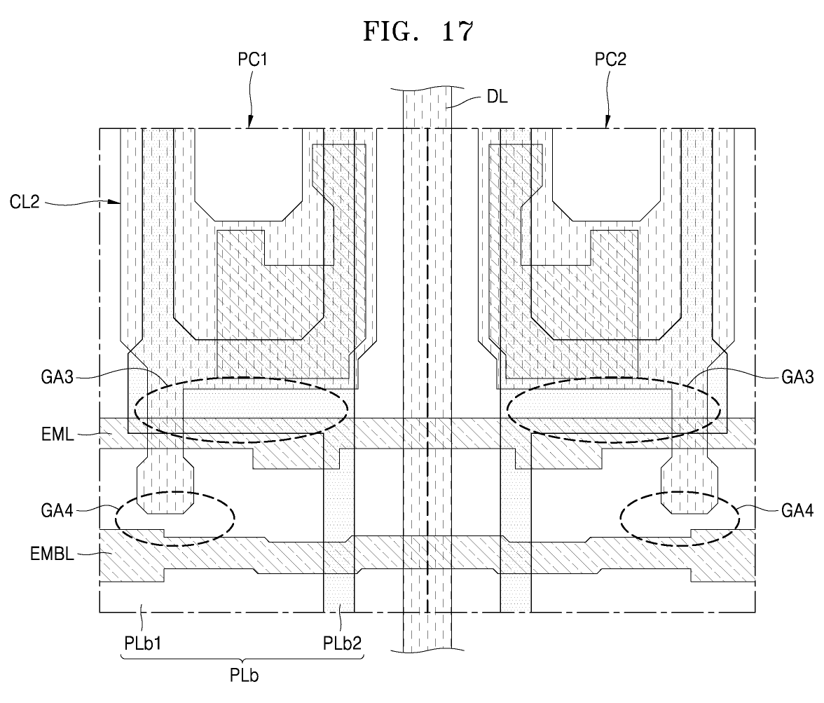

FIG. 17 is a plan view of some components of a display apparatus, according to an embodiment. In FIG. 17, like reference numerals as FIG. 15 refer to like components.

Referring to FIG. 17, the areas of the first wire PLb of the first pixel circuit PC1 covering the third gap GA3 and the fourth gap GA4 may be the same as the areas of the first wire PLb of the second pixel circuit PC2 covering the third gap GA3 and the fourth gap GA4.

The first wire PLb may cover the third gap GA3 and expose the fourth gap GA4. Such an arrangement may be applied identically to the first pixel circuit PC1 and the second pixel circuit PC2. Accordingly, the same parasitic capacitance may be formed in the first pixel circuit PC1 and the second pixel circuit PC2.

In an embodiment, the first emission control line EM1 may include the third gap GA3 spaced apart from the first electrode layer CL2 in a plan view. The first wire PLb may cover the third gap GA3 in both the first pixel circuit PC1 and the second pixel circuit PC2. The area of the first wire PLb covering the third gap GA3 in the first pixel circuit PC1 may be about equal to the area of the first wire PLb covering the third gap GA3 in the second pixel circuit PC2, which may reduce variation in parasitic capacitance between adjacent pixel circuits PC.

In an embodiment, the second emission control line EM2 may include the fourth gap GA4 spaced apart from the first electrode layer CL2 in a plan view. Similar to the arrangement described for the third gap GA3, the first wire PLb may at least partially cover the fourth gap GA4 in both the first pixel circuit PC1 and the second pixel circuit PC2. The area of the first wire PLb covering the fourth gap GA4 in the first pixel circuit PC1 may be about equal to the area of the first wire PLb covering the fourth gap GA4 in the second pixel circuit PC2, which may help balance parasitic capacitance between the adjacent pixel circuits.

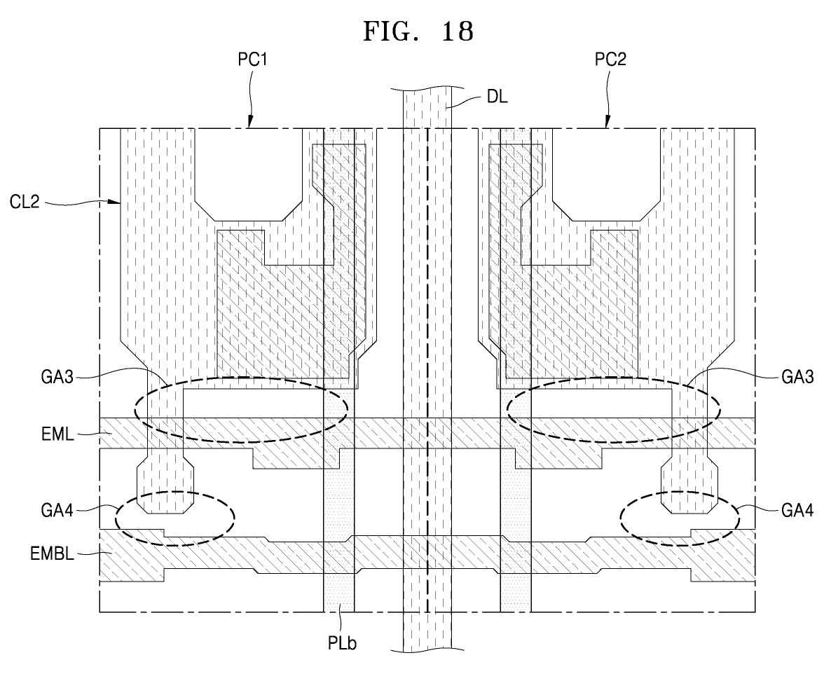

Referring to FIG. 18, the areas of the first wire PLb of the first pixel circuit PC1 covering the third gap GA3 and the fourth gap GA4 may be the same as the areas of the first wire PLb of the second pixel circuit PC2 covering the third gap GA3 and the fourth gap GA4.

The first wire PLb may expose most of the third gap GA3, and expose the fourth gap GA4. Such an arrangement may be applied identically to the first pixel circuit PC1 and the second pixel circuit PC2. Accordingly, the same parasitic capacitance may be formed in the first pixel circuit PC1 and the second pixel circuit PC2.

Embodiments described above with reference to FIGS. 11 to 18 may be variously modified, such as, for example, being implemented individually or in combination with each other. According to the above-described embodiments, a difference in luminance between light-emitting diodes may be reduced by adjusting values of capacitances of storage capacitors and/or holding capacitors of pixel circuits sharing the data line DL.

The display apparatus according to the above-described embodiments may be applied to any one of various electronic devices. An electronic device according to an embodiment may include the display apparatus described above, and further include a module or device having other additional functions, in addition to the display apparatus.

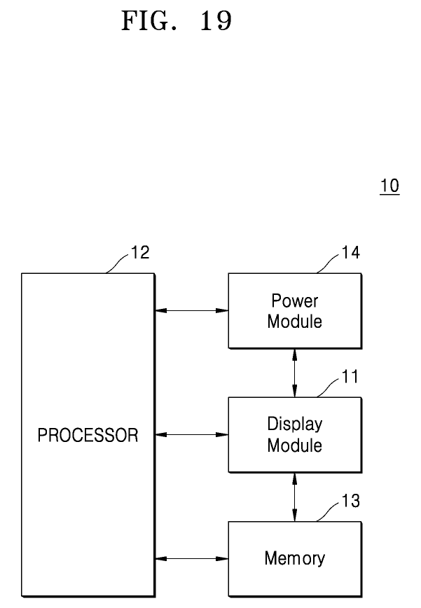

FIG. 19 is a block diagram of an electronic device 10 according to an embodiment. Referring to FIG. 19 the electronic device 10 according to an embodiment may include a display module 11, a processor 12, a memory 13, and a power module 14.

The processor 12 may include at least one of, for example, a central processing unit (CPU), an application processor (AP), a graphics processing unit (GPU), a communication processor (CP), an image signal processor (ISP), and a controller.

The memory 13 may store data information necessary for operations of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as, for example, a power adapter or a battery device, and a power conversion module configured to convert power supplied by the power supply module to generate power required for operations of the electronic device 10.

At least one of the components of the electronic device 10 may be included in a display apparatus according to the above-described embodiments. Some of the individual modules functionally included in one module may be included in the display apparatus and others may be provided separately from the display apparatus. For example, the display apparatus may include the display module 11, and the processor 12, the memory 13, and the power module 14 may be provided in the form of other devices in the electronic device 10 other than the display apparatus.

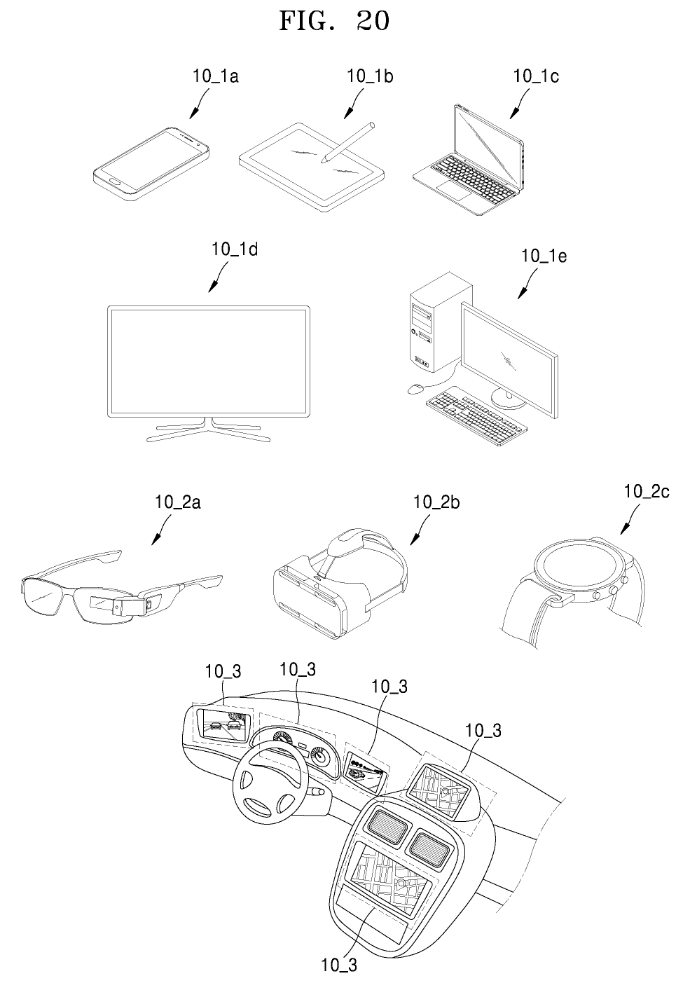

FIG. 20 illustrates a plurality of schematic diagrams of electronic devices according to various embodiments.

Referring to FIG. 20, various electronic devices to which a display apparatus according to embodiments is applied may include not only image display electronic devices, such as, for example, a smartphone 10_1a, a tablet personal computer (PC) 10_1b, a laptop PC 10_1c, a television (TV) 10_1d, and a desk monitor 10_1e, but also wearable electronic devices, such as, for example, smart glasses 10_2a, a head-mount display 10_2b, and a smart watch 10_2c, and vehicle electronic devices 10_3 including display modules such as, for example, a dashboard of a vehicle, a center fascia, a center information display (CID) provided on a dashboard, and a room mirror display.

As described above, a display apparatus and an electronic device, according to embodiments of the present disclosure, may provide substantially the same parasitic capacitance for each pixel circuit, resulting in high reliability.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display apparatus, comprising:
a substrate;
a first-first gate line and a first-second gate line, which are spaced apart from each other and extend in a first direction on the substrate;
a data line extending in a second direction crossing the first direction; and
a first pixel circuit and a second pixel circuit, which are disposed along the first direction with the data line disposed therebetween,
wherein the first pixel circuit is connected to the first-first gate line and the second pixel circuit is connected to the first-second gate line, and
each of the first pixel circuit and the second pixel circuit comprises:
a first transistor including a first semiconductor layer and a first gate electrode;
a second transistor including a second semiconductor layer and a second gate electrode, which are connected to the data line;
a first electrode layer connected to the first semiconductor layer, overlapping the first gate electrode, and including a first gap spaced apart from the second gate electrode in a plan view; and
a first wire disposed above the first electrode layer, extending in the second direction, and covering at least a portion of the first gap in the plan view.

2. The display apparatus of claim 1, wherein each of the first pixel circuit and the second pixel circuit further comprises a third semiconductor layer integrated with the second semiconductor layer, and a third gate electrode overlapping the third semiconductor layer,
the third gate electrode includes a second gap spaced apart from the first electrode layer in the plan view, and
the first wire covers at least a portion of the second gap in the plan view.

3. The display apparatus of claim 2, wherein the first wire is branched into a first branch and a second branch,
the first branch covers at least a portion of the first gap and the second branch covers at least a portion of the second gap, and
the second branch of the first pixel circuit is continuously disposed in an area overlapping the first electrode layer and the second branch of the second pixel circuit includes a disconnected gap in the area overlapping the first electrode layer.

4. The display apparatus of claim 1, wherein each of the first pixel circuit and the second pixel circuit further comprises a third semiconductor layer integrated with the second semiconductor layer, and a third gate electrode overlapping the third semiconductor layer,
the third gate electrode includes a second gap spaced apart from the first electrode layer in the plan view, and
the first wire exposes the second gap in the plan view.

5. The display apparatus of claim 4, wherein an area of the first wire of the first pixel circuit overlapping the first electrode layer is different from an area of the first wire of the second pixel circuit overlapping the first electrode layer.

6. The display apparatus of claim 1, further comprising:
a first emission control line and a second emission control line, which extend in the first direction,
wherein the first emission control line includes a third gap that is a portion spaced apart from the first electrode layer in the plan view, and
an area of the first wire covering the third gap in the first pixel circuit is about equal to an area of the first wire covering the third gap in the second pixel circuit.

7. The display apparatus of claim 6, wherein the second emission control line includes a fourth gap that is a portion spaced apart from the first electrode layer in the plan view, and
an area of the first wire covering the fourth gap in the first pixel circuit is about equal to an area of the first wire covering the fourth gap in the second pixel circuit.

8. The display apparatus of claim 6, wherein the first electrode layer at least partially overlaps the first emission control line.

9. The display apparatus of claim 1, wherein the first pixel circuit and the second pixel circuit share the data line.

10. The display apparatus of claim 1, further comprising:
a first light-emitting diode connected to the first pixel circuit; and
a second light-emitting diode connected to the second pixel circuit,
wherein the first light-emitting diode and the second light-emitting diode emit light of a same color.

11. The display apparatus of claim 1, wherein each of the first pixel circuit and the second pixel circuit further comprises a holding capacitor, and
a capacity of the holding capacitor of the first pixel circuit is different from a capacity of the holding capacitor of the second pixel circuit.

12. The display apparatus of claim 11, wherein the holding capacitor comprises:
a first holding electrode disposed below the first semiconductor layer;
a second holding electrode disposed in a same layer as the first semiconductor layer;
a third holding electrode integrated with the first electrode layer; and
a fourth holding electrode disposed above the third holding electrode,
wherein the fourth holding electrode is integrated with the first wire.

13. The display apparatus of claim 1, wherein the first wire includes a wire configured to transmit a constant voltage.

14. An electronic device comprising a display apparatus, wherein the display apparatus comprises:
a substrate;
a first-first gate line and a first-second gate line, which are spaced apart from each other and extend in a first direction on the substrate;
a data line extending in a second direction crossing the first direction; and
a first pixel circuit and a second pixel circuit, which are disposed along the first direction with the data line disposed therebetween,
wherein the first pixel circuit is connected to the first-first gate line and the second pixel circuit is connected to the first-second gate line, and
each of the first pixel circuit and the second pixel circuit comprises:
a first transistor including a first semiconductor layer and a first gate electrode;
a second transistor including a second semiconductor layer and a second gate electrode, which are connected to the data line;
a first electrode layer connected to the first semiconductor layer, overlapping the first gate electrode, and including a first gap spaced apart from the second gate electrode in a plan view; and
a first wire disposed above the first electrode layer, extending in the second direction, and covering at least a portion of the first gap in the plan view.

15. The electronic device of claim 14, wherein each of the first pixel circuit and the second pixel circuit further comprises a third semiconductor layer integrated with the second semiconductor layer, and a third gate electrode overlapping the third semiconductor layer,
the third gate electrode includes a second gap spaced apart from the first electrode layer in the plan view, and
an area of the first wire of the first pixel circuit covering the second gap is about equal to an area of the first wire of the second pixel circuit covering the second gap.

16. The electronic device of claim 14, wherein each of the first pixel circuit and the second pixel circuit further comprises a holding capacitor, and
a capacity of the holding capacitor of the first pixel circuit is different from a capacity of the holding capacitor of the second pixel circuit.

17. The electronic device of claim 14, further comprising:
a first emission control line and a second emission control line, which extend in the first direction,
wherein the first emission control line includes a third gap that is a portion spaced apart from the first electrode layer in the plan view, and
an area of the first wire covering the third gap in the first pixel circuit is about equal to an area of the first wire covering the third gap in the second pixel circuit.

18. The electronic device of claim 14, wherein the first pixel circuit and the second pixel circuit share the data line.

19. The electronic device of claim 14, wherein the first wire includes a wire configured to transmit a constant voltage.

20. The electronic device of claim 14, wherein the electronic device is one of a smartphone, a tablet personal computer (PC), a laptop PC, a television (TV), a desk monitor, smart glasses, a head-mount display, a smart watch, a dashboard of a vehicle, a center fascia, a center information display (CID), and a room mirror display.
